(19) United States
(12) Patent Application Publication
(10) Pub. No.: US 2024/0030126 A1
(43) Pub. Date: Jan. 25, 2024

(54) MICROELECTRONICS PACKAGE WITH VERTICALLY STACKED WAFER SLICES AND PROCESS FOR MAKING THE SAME

(71) Applicant: Qorvo US, Inc., Greensboro, NC (US)

(72) Inventor: Julio C. Costa, Oak Ridge, NC (US)

(21) Appl. No.: 18/254,159

(22) PCT Filed: Dec. 9, 2021
(86) PCT No.: PCT/US2021/062509

§ 371 Date: May 23, 2023

Related U.S. Application Data
(60) Provisional application No. 63/124,464, filed on Dec. 11, 2020.

(51) Int. Cl. H01L 23/522; H01L 23/00; H01L 23/48

(52) U.S. Cl. CPC H01L 23/5226; H01L 24/32; H01L 23/481; H01L 24/13; H01L 2224/32145; H01L 2224/13

(57) ABSTRACT

The present disclosure relates to a microelectronics package with a vertically stacked structure of two or more wafer slices. A first wafer slice includes a first device region and a through-via connected to the first device region through a first connecting layer. A second wafer slice, which is vertically stacked underneath the first wafer slice, includes a second device region and a top via connected to the second device region through a second connecting layer. The top via in the second wafer slice is in contact with the through-via in the first wafer slice, such that the first device region is electrically connected to the second first device region. Herein, silicon crystal, which has no germanium, nitrogen, or oxygen content, does not exist between the first device region and the second device region.

### RELATED APPLICATIONS

This application claims the benefit of provisional patent application Ser. No. 63/124,464, filed Dec. 11, 2020, the disclosure of which is hereby incorporated herein by reference in its entirety.

### FIELD OF THE DISCLOSURE

The present disclosure relates to a microelectronics package and a process for making the same, and more particularly to a microelectronics package with a vertically stacked structure of two or more wafer slices.

### BACKGROUND

With the popularity of portable consumer electronic products, such as smart phones, tablet computers, and so forth, stacked-device assemblies are becoming more and more attractive in microelectronics packages to achieve electronics densification in a small footprint. However, the thickness of each stacked semiconductor device may result in a large thickness of the microelectronics package, which may not meet low-profile requirements for modern portable products. Such low-profile requirements significantly limit the number of semiconductor dies that can be stacked.

On the other hand, substrates on which the semiconductor devices, especially radio frequency (RF) devices, are fabricated play an important role in achieving high level performance. Although conventional silicon substrates may benefit from low cost of silicon materials, a large scale capacity of wafer production, well-established semiconductor design tools, and well-established semiconductor manufacturing techniques, the conventional silicon substrates may have two undesirable properties for the RF devices: harmonic distortion and low resistivity values. The harmonic distortion is a critical impediment to achieve high level linearity in the RF devices built over silicon substrates.

Accordingly, to reduce deleterious harmonic distortion of the RF devices, and to accommodate the low-profile requirements for portable products, it is therefore an object of the present disclosure to provide an improved package design with enhanced performance and a reduced package size without expensive and complicated processes.

### SUMMARY

The present disclosure describes a microelectronics package with a vertically stacked structure of two or more wafer slices and a process for making the same. The disclosed microelectronics package includes a first wafer slice and a second wafer slice vertically stacked underneath the first wafer slice. The first wafer slice has a first device region at a top of the first wafer slice, a first passivation layer underneath the first device region, and a first through-via that vertically extends through the first passivation layer and into the first device region. Herein, the first device region includes a first front-end-of-line (FEOL) portion and a first back-end-of-line (BEOL) portion that is over the first FEOL portion and includes at least one first connecting layer configured to electrically connect the first FEOL portion and the first through-via. The second wafer slice includes a top bonding layer at a top of the second wafer slice and is configured to bond to the first wafer slice, a second device region underneath the top bonding layer, and a top via that vertically extends through the top bonding layer and into the second device region. Herein, the second device region includes a second FEOL portion and a second BEOL portion that is over the second FEOL portion and includes at least one second connecting layer configured to electrically connect the second FEOL portion and the top via. The top via is in contact with the first through-via, such that the second FEOL portion is electrically connected to the first FEOL portion through the at least one second connecting layer, the top via, the first through-via, and the at least one first connecting layer.

In one embodiment of the microelectronics package, silicon crystal, which has no germanium, nitrogen, or oxygen content, does not exist between the first device region and the second device region.

In one embodiment of the microelectronics package, the first BEOL portion includes first dielectric layers, and a number of first connecting layers that includes the at least one first connecting layer. Some of the first connecting layers are partially covered by the first dielectric layers and are configured to electrically connect the first FEOL portion to components outside the first device region. The first FEOL portion includes a first contact layer underneath the first BEOL portion, a first active layer underneath the first contact layer, and first isolation sections underneath the first contact layer and surrounding the first active layer. The second BEOL portion includes second dielectric layers, and a number of second connecting layers that includes the at least one second connecting layer. Some of the second connecting layers are partially covered by the second dielectric layers and are configured to electrically connect the second FEOL portion to components outside the second device region. The second FEOL portion includes a second contact layer underneath the second BEOL portion, a second active layer underneath the second contact layer, and second isolation sections underneath the second contact layer and surrounding the second active layer.

According to one embodiment, the microelectronics package further includes a number of bump structures, which is formed over the first wafer slice, and electrically coupled to the first FEOL portion through the first connecting layers in the first BEOL portion.

In one embodiment of the microelectronics package, the first through-via of the first wafer slice does not extend toward or into portions of the first device region where the first active layer is located, and the top via of the second wafer slice does not extend toward or into portions of the second device region where the second active layer is located.

In one embodiment of the microelectronics package, the first isolation sections extend vertically beyond a bottom surface of the first active layer to define a first opening within the first isolation sections and underneath the first active layer.

In one embodiment of the microelectronics package, a bottom surface of each first isolation section and the bottom surface of the first active layer are coplanar, such that the first FEOL portion of the first device region has a flat bottom surface.

In one embodiment of the microelectronics package, the first passivation layer in the first wafer slice continuously covers the first active layer and at least covers bottom surfaces of the first isolation sections. The first passivation layer is formed of silicon oxide, and the top bonding layer in the second wafer slice is formed of silicon oxide. The first passivation layer is at a bottom of the first wafer slice and directly bonded with the top bonding layer of the second wafer slice.

In one embodiment of the microelectronics package, the first wafer slice further includes a first enhancement region underneath the first passivation layer and a first bottom bonding layer underneath the first enhancement region. Herein, the first passivation layer in the first wafer slice continuously covers the first active layer and at least covers bottom surfaces of the first isolation sections. The first through-via extends through the first bottom bonding layer, the first enhancement region, the first passivation layer and into the first device region. The first bottom bonding layer in the first wafer slice is formed of silicon oxide, and the top bonding layer in the second wafer slice is formed of silicon oxide. The first bottom bonding layer is at a bottom of the first wafer slice and directly bonded with the top bonding layer of the second wafer slice.

In one embodiment of the microelectronics package, the first passivation layer is formed of silicon oxide. The first enhancement region includes a first barrier layer underneath the first passivation layer and a first thermally conductive layer underneath the first barrier layer and over the first bottom bonding layer. The first barrier layer is formed of silicon nitride with a thickness between 0.2 μm and 10 μm, and the first thermally conductive layer is formed of aluminum nitride with a thickness between 0.1 μm and 20 μm.

In one embodiment of the microelectronics package, the second isolation sections extend vertically beyond a bottom surface of the second active layer to define a second opening within the second isolation sections and underneath the second active layer.

In one embodiment of the microelectronics package, a bottom surface of each second isolation section and the bottom surface of the second active layer are coplanar, such that the second FEOL portion of the second device region has a flat bottom surface.

In one embodiment of the microelectronics package, the second wafer slice further includes a second passivation layer underneath the second FEOL portion of the second device region. Herein, the second passivation layer continuously covers the second active layer and at least covers bottom surfaces of the second isolation sections. The second passivation layer is formed of silicon oxide.

In one embodiment of the microelectronics package, the second wafer slice further includes a second enhancement region underneath the second passivation layer. Herein, the second enhancement region includes a second barrier layer underneath the second passivation layer and a second thermally conductive layer underneath the second barrier layer. The second barrier layer is formed of silicon nitride with a thickness between 0.2 μm and 10 μm, and the second thermally conductive layer is formed of aluminum nitride with a thickness between 0.1 μm and 20 μm.

According to one embodiment, the microelectronics package further includes a mold compound formed underneath the second enhancement region. The mold compound has a thermal conductivity greater than 1 W/m·K and a dielectric constant less than 8.

In one embodiment of the microelectronics package, the first FEOL portion provides a switch field-effect transistor (FET), and the second FEOL portion provides another switch FET.

According to one embodiment, the microelectronics package further includes a third wafer slice vertically stacked underneath the second wafer slice. The third wafer slice includes a third top bonding layer at a top of the third wafer slice and configured to bond to the second wafer slice, a third device region underneath the third top bonding layer, and a third top via that vertically extends through the third top bonding layer and into the third device region. Herein, the second wafer slice further includes a second passivation layer underneath the second device region, and a second through-via that vertically extends through the second passivation layer and into the second device region. The at least one second connecting layer is configured to electrically connect the second FEOL portion and the second through-via. The third device region includes a third FEOL portion and a third BEOL portion that is over the third FEOL portion and includes at least one third connecting layer configured to electrically connect the third FEOL portion and the third top via. The third top via is in contact with the second through-via, such that the third FEOL portion is electrically connected to the second FEOL portion through the at least one third connecting layer, the third top via, the second through-via, and the at least one second connecting layer.

In one embodiment of the microelectronics package, silicon crystal, which has no germanium, nitrogen, or oxygen content, does not exist between the second device region and the third device region.

In one embodiment of the microelectronics package, the second passivation layer is formed of silicon oxide, and the third top bonding layer in the third wafer slice is formed of silicon oxide. The second passivation layer is at a bottom of the second wafer slice and directly bonded with the third top bonding layer of the third wafer slice.

In one embodiment of the microelectronics package, the second wafer slice further includes the second enhancement region underneath the second passivation layer and a second bottom bonding layer underneath the second enhancement region. Herein, the second through-via extends through the second bottom bonding layer, the second enhancement region, the second passivation layer and into the second device region. The second bottom bonding layer in the second wafer slice is formed of silicon oxide, and the third top bonding layer in the third wafer slice is formed of silicon oxide. The second bottom bonding layer is at a bottom of the second wafer slice and directly bonded with the third top bonding layer of the third wafer slice.

In one embodiment of the microelectronics package, the third wafer slice further includes a third passivation layer underneath the third FEOL portion of the third device region. The third passivation layer is formed of silicon oxide.

In one embodiment of the microelectronics package, the third wafer slice further includes a third enhancement region underneath the third passivation layer. The third enhancement region includes a third barrier layer underneath the third passivation layer and a third thermally conductive layer underneath the third barrier layer. The third barrier layer is formed of silicon nitride with a thickness between 0.2 μm and 10 μm, and the third thermally conductive layer is formed of aluminum nitride with a thickness between 0.1 μm and 20 μm.

According to one embodiment, the microelectronics package further includes a mold compound formed underneath the third enhancement region. The mold compound has a thermal conductivity greater than 1 W/m·K and a dielectric constant less than 8.

According to an exemplary process, a first precursor wafer slice, which includes a first device region, a first interfacial layer, and a first silicon handle substrate, is firstly provided. The first device region includes a first front-end-of-line (FEOL) portion having first isolation sections and a first active layer, which is surrounded by the first isolation sections and does not extend vertically beyond the first isolation sections. The first individual interfacial layer, which is formed of silicon germanium (SiGe), is underneath the first active layer, and the first silicon handle substrate is underneath the first individual interfacial layer. Next, the first silicon handle substrate is completely removed to provide a first etched wafer slice, and a first passivation layer is formed to cover an entire bottom side of the first etched wafer slice. The first passivation layer covers a bottom surface of the first active layer and a bottom surface of each first isolation section. A through-via cavity, which extends through the first passivation layer and into the first device region, is then formed, and a through-via is formed in the through-via cavity to provide a first wafer slice. In addition, a second precursor wafer slice, which includes a second device region, a second interfacial layer, and a second silicon handle substrate is also provided. The second device region includes a second FEOL portion having second isolation sections and a second active layer, which is surrounded by the second isolation sections and does not extend vertically beyond the second isolation sections. The second individual interfacial layer, which is formed of SiGe, is underneath the second active layer, and the second silicon handle substrate is underneath the second individual interfacial layer. Next, a top bonding layer is formed over the second device region, and a top via cavity that extends through the second top bonding layer and into the second device region is formed. A top via is then formed in the top via cavity to provide a bonding-ready wafer slice. The first wafer slice is bonded to the bonding-ready wafer slice to provide a precursor package. Herein, the through-via and the top via are vertically aligned with each other and are electrically connected, such that the first device region in the first wafer slice and the second device region in the bonding-ready wafer slice are electrically connected.

According to one embodiment, the exemplary process further includes removing the second silicon handle substrate completely from the precursor package to provide a first etched package, and applying a mold compound underneath the first etched package to provide a molded package.

According to one embodiment, the exemplary process further includes removing the second interfacial layer to expose a bottom surface of the second active layer after removing the second silicon handle substrate. Then, a second passivation layer, which is formed of silicon oxide, is formed continuously underneath the bottom surface of the second active layer and a bottom surface of each second isolation section.

According to one embodiment, the exemplary process further includes forming an enhancement region underneath the second passivation layer. Herein, the enhancement region includes a barrier layer underneath the second passivation layer and a thermally conductive layer underneath the barrier layer. The barrier layer is formed of silicon nitride with a thickness between 0.2 μm and 10 μm, and the thermally conductive layer is formed of aluminum nitride with a thickness between 0.1 μm and 20 μm. The mold compound is formed underneath the thermally conductive layer.

According to one embodiment, the exemplary process further includes attaching the first precursor wafer slice to a temporary carrier via an attaching layer before the first silicon handle substrate is removed, and detaching the temporary carrier and cleaning the attaching layer from the molded package after the mold compound is applied.

In one embodiment of the exemplary process, the first passivation layer is formed of silicon oxide, and the top bonding layer is formed of silicon oxide. The first passivation layer is at a bottom of the first wafer slice and directly bonded with the top bonding layer over the second device region.

According to one embodiment, the exemplary process further includes, after removing the first silicon handle substrate and before forming the first passivation layer, removing the first interfacial layer to expose a bottom surface of the first active layer. Herein, the first passivation layer is directly formed underneath the bottom surface of the first active layer and the bottom surface of each first isolation section.

According to one embodiment, the exemplary process further includes, after forming the first passivation layer, forming an enhancement region underneath the first passivation layer and forming a bottom bonding layer underneath the enhancement region. Herein, the enhancement region includes at least one of a controller barrier layer and a controller thermally conductive layer. The through-via extends through the bottom bonding layer, the enhancement region, the first passivation layer and into the first device region. The bottom bonding layer is formed of silicon oxide, and the top bonding layer is formed of silicon oxide. The bottom bonding layer is at a bottom of the first wafer slice and directly bonded with the top bonding layer over the second device region.

According to one embodiment, the exemplary process further includes, before the first wafer slice is bonded to the bonding-ready wafer slice, planarizing a backside of the first wafer slice, such that the through-via is recessed compared to a bottom surface of the bottom bonding layer; and planarizing a topside of the bonding-ready wafer slice, such that the top via is recessed compared to a top surface of the top bonding layer.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 illustrates an exemplary microelectronics package with a vertically stacked structure of two wafer slices according to one embodiment of the present disclosure.

FIG. 2 illustrates an exemplary microelectronics package with a vertically stacked structure of three wafer slices according to one embodiment of the present disclosure.

FIG. 3 illustrates an alternative microelectronics package with a vertically stacked structure of three wafer slices according to one embodiment of the present disclosure.

FIGS. 4A-15 provide exemplary steps that illustrate a process to fabricate the exemplary microelectronics package illustrated in FIG. 1.

FIGS. 16-30 provide exemplary steps that illustrate a process to fabricate the exemplary microelectronics package illustrated in FIG. 2.

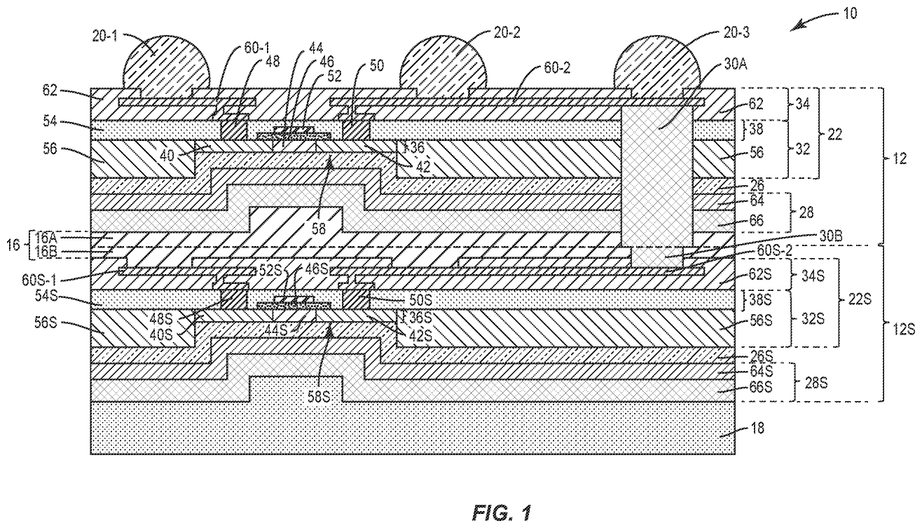

It will be understood that for clear illustrations, FIGS. 1-30 may not be drawn to scale.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

FIG. 1 illustrates an exemplary microelectronics package 10 with a vertically stacked structure of two wafer slices according to one embodiment of the present disclosure. For the purpose of this illustration, the microelectronics package 10 includes a first wafer slice 12 and a second wafer slice 12S vertically stacked with the first wafer slice 12. Herein, the first wafer slice 12 and the second wafer slice 12S are bonded at a first bonding region 16, which includes a first bottom bonding layer 16A from the first wafer slice 12 and a second top bonding layer 16B from the second wafer slice 12S. In addition, the microelectronics package 10 may also include a mold compound 18 underneath the second wafer slice 12S, and multiple bump structures 20 over the first wafer slice 12. In different applications, the first wafer slice 12 and the second wafer slice 12S may include different devices.

In one embodiment, the first wafer slice 12 implements a switching function. In the first wafer slice 12, a first device region 22 is at a top of the first wafer slice 12, a first passivation layer 26 is underneath the first device region 22, a first enhancement region 28 is underneath the first passivation layer 26, the first bottom bonding layer 16A is underneath the first enhancement region 28, and a first through-via 30A extends through the first bottom bonding layer 16A, the first enhancement region 28, and the first passivation layer 26, and extends into the first device region 22.

In detail, the first device region 22 includes a first front-end-of-line (FEOL) portion 32 and a first back-end-of-line (BEOL) portion 34. Each bump structure 20 is formed over the first BEOL portion 34, and the first FEOL portion 32 is formed underneath the first BEOL portion 34. In one embodiment, the first FEOL portion 32 may be configured to provide a first switch field-effect transistor (FET). The first FEOL portion 32 includes a first active layer 36 and a first contact layer 38 over the first active layer 36. The first active layer 36 may include a first source 40, a first drain 42, and a first channel 44 between the first source 40 and the first drain 42. In some applications, there might be a first body (not shown) residing underneath the first active layer 36.

The first contact layer 38 is formed over the first active layer 36 and includes a first gate structure 46, a first source contact 48, a first drain contact and a first gate contact 52. The first gate structure 46 may be formed of silicon oxide, and extends horizontally over the first channel 44 (i.e., from over the first source 40 to over the first drain 42). The first source contact 48 is connected to and over the first source 40, the first drain contact 50 is connected to and over the first drain 42, and the first gate contact 52 is connected to and over the first gate structure 46. A first insulating material 54 may be formed around the first source contact 48, the first drain contact 50, the first gate structure 46, and the first gate contact 52 to electrically separate the first source the first drain 42, and the first gate structure 46. In different applications, the first FEOL portion 32 may have different FET configurations or provide different device components.

In addition, the first FEOL portion 32 also includes first isolation sections 56, which reside underneath the first insulating material 54 of the first contact layer 38 and surround the first active layer 36 (and surround the first body if the first body exists, not shown). The first isolation sections 56 are configured to electrically separate the first active layer 36 from other devices (not shown) formed in the same first wafer slice 12. Herein, the first isolation sections 56 may extend from a bottom surface of the first contact layer 38 and vertically beyond a bottom surface of the first active layer 36 to define a first opening 58 that is within the first isolation sections 56 and underneath the first active layer 36. The first isolation sections 56 may be formed of silicon dioxide, which may be resistant to etching chemistries such as tetramethylammonium hydroxide (TMAH), xenon difluoride (XeF₂), potassium hydroxide (KOH), sodium hydroxide (NaOH), or acetylcholine (ACH), and may be resistant to a dry etching system, such as a reactive ion etching (RIE) system with a chlorine-based gas chemistry or a fluorine-based gas chemistry.

The first BEOL portion 34 is over the first FEOL portion 32 and includes multiple first connecting layers 60 formed within first dielectric layers 62. The first connecting layers 60 may have one or more top portions not covered by the first dielectric layers 62, such that each bump structure 20 can be electrically connected to a corresponding uncovered top portion of the first connecting layers 60. In addition, the first connecting layers 60 in the first BEOL portion 34 are electrically connected to the first FEOL portion 32. Therefore, the first connecting layers 60 provide electrical connections between the first FEOL portion 32 to the bump structures 20. For the purpose of this illustration, one of the first connecting layers 60-1 electrically connects the first source contact 48 to a first bump structure 20-1, and another one of the first connecting layers 60-2 electrically connects the first drain contact 50 to a second bump structure 20-2 and a third bump structure 20-3. In different applications, there might be more first connecting layers 60 and more/fewer bump structures 20 connected to the first connecting layers 60 in a different configuration. Some of the first connecting layers 60 in the first BEOL portion 34 may be used for internal connections, but not connected to any bump structure 20 (not shown).

In some applications, the first active layer 36 in the first FEOL portion 32 may be passivated to achieve proper low levels of current leakage in the first device region 22. The passivation may be accomplished with the first passivation layer 26 underneath the first FEOL portion 32 of the first device region 22. The first passivation layer 26 may be formed of silicon oxide with a thickness between 10 nm and 5000 nm. Herein, the first passivation layer 26 may extend over an entire bottom surface of the first FEOL portion 32, such that the first passivation layer 26 continuously covers exposed surfaces within the first opening 58 and bottom surfaces of the first isolation sections 56. In some applications, the first passivation layer 26 may only cover a bottom surface of the first active layer 36 and reside within the first opening 58 (not shown). In some applications, the first passivation layer 26 may be omitted (not shown).

The first enhancement region 28 is formed underneath the first passivation layer 26. If there is no first passivation layer 26, the first enhancement region 28 is formed underneath the first device region 22 and extends over the entire bottom surface of the first FEOL portion 32, such that the first enhancement region 28 continuously covers exposed surfaces within the first opening 58 and bottom surfaces of the first isolation sections 56 (not shown). If the first passivation layer 26 is only formed underneath the first active layer 36 and within the first opening 58, the first enhancement region 28 still continuously covers exposed surfaces (including the first passivation layer 26) within the first opening 58 and the bottom surfaces of the first isolation sections 56 (not shown). The first enhancement region 28 is configured to enhance reliability and/or thermal performance of the first device region 22, especially the first active layer 36 in the first device region 22.

In one embodiment, the first enhancement region 28 includes a first barrier layer 64 formed underneath the first passivation layer 26, and a first thermally conductive layer 66 formed underneath the first barrier layer 64. Herein, the first barrier layer 64 may be formed of silicon nitride with a thickness between 2000 Å and 10 μm. The first barrier layer 64 is configured to provide a superior barrier to moisture and impurities, which could diffuse into the first channel 44 of the first active layer 36 and cause reliability concerns in the device. Moisture, for example, may diffuse readily through a silicon oxide layer (like the first passivation layer 26), but even a thin nitride layer (like the first barrier layer 64) reduces the diffusion of the water molecule by several orders of magnitude, acting as an ideal barrier. In addition, the first barrier layer 64 may also be engineered so as to provide additional tensile strain to the first device region 22. Such strain may be beneficial in providing additional improvement of electron mobility in n-channel devices. In some applications, the first barrier layer 64 formed of silicon nitride may further passivate the first active layer 36. In such case, there may be no need for the first passivation layer 26.

The first thermally conductive layer 66, which may be formed of aluminum nitride with a thickness between 0.1 μm and 20 μm, could provide superior thermal dissipation for the first device region 22, in the order of 275 W/mk while retaining superior electrically insulating characteristics. The first thermally conductive layer 66 might be very important to the overall thermal behavior of the stacked wafer slices. If power dissipation is not a concern, then the first thermally conductive layer 66 may be omitted. Due to different application needs, the entire first enhancement region 28 might be omitted, or the first barrier layer 64 might be omitted while the first thermally conductive layer 66 might be retained.

The first wafer slice 12 also includes the first bottom bonding layer 16A for bonding to the second wafer slice 12S. The first bottom bonding layer 16A may be formed of silicon oxide. If the first wafer slice 12 includes the first enhancement region 28 with the first barrier layer 64 and the first thermally conductive layer 66, the first bottom bonding layer 16A is formed directly underneath the first thermally conductive layer 66. If the first barrier layer 64 is retained while the first thermally conductive layer 66 is omitted, the first bottom bonding layer 16A is formed directly underneath the first barrier layer 64 (not shown). If the first barrier layer 64 is omitted while the first thermally conductive layer 66 is retained, the first bottom bonding layer 16A is formed directly underneath first thermally conductive layer 66 (not shown). If the entire first enhancement region 28 is omitted in the first wafer slice 12, there might not be a need for the first bottom bonding layer 16A, since the first passivation layer 26, which is formed of silicon oxide, may also function as the bottom bonding layer for bonding to the second wafer slice 12S (not shown).

The first through-via 30A extends through the first bottom bonding layer 16A, the first enhancement region 28, and the first passivation layer 26, and extends into the first device region 22. The first through-via 30A does not extend toward or into the portions of the first device region 22 where the first active layer 36 is located. The first through-via 30A (with a second top via 30B, described in following paragraphs) is configured to electrically connect the first wafer slice 12 and the second wafer slice 12S. For the purpose of this illustration, the first through-via 30A is connected to the first active layer 36 through the first connecting layer 60-2 in the first BEOL portion 34. The first through-via 30A may be formed of copper.

The second wafer slice 12S includes the second top bonding layer 16B at a top of the second wafer slice 12S for bonding to the first bottom bonding layer 16A, so as to bond to the first wafer slice 12. The first bottom bonding layer 16A and the second top bonding layer 16B are formed of a same material, such as silicon oxide, and are combined directly together as the first bonding region 16. If the first wafer slice 12 does not include the first enhancement region 28 and the first bottom bonding layer 16A, the second top bonding layer 16B at the top of the second wafer slice 12S might be directly bonded to the first passivation layer 26 of the first wafer slice 12.

Similar to the first wafer slice 12, the second wafer slice 12S also includes a second device region 22S formed underneath the second top bonding layer 16B, the second top via 30B that extends through the second top bonding layer 16B and into the second device region 22S, a second passivation layer 26S underneath the second device region 22S, and a second enhancement region 28S underneath the second passivation layer 26S.

Notice that, between the first device region 22 and the second device region 22S, there are the first bonding region 16 (the first bottom bonding layer 16A and the second top bonding layer 16B), optionally the first enhancement region 28 (the first barrier layer 64 and/or the first thermally conductive layer 66), optionally the first passivation layer 26, and the first via structure 30 (the first through-via 30A and the second top via 30B). In a desired case, silicon crystal (which has no germanium, nitrogen, or oxygen content) does not exist between the first device region 22 and the second device region 22S. Each of the first barrier layer 64, the first thermally conductive layer 66, and the first bonding region 16 is formed of silicon composite, but not silicon crystal.

The second device region 22S includes a second FEOL portion 32S and a second BEOL portion 34S. The second BEOL portion 34S is formed underneath the second top bonding layer 16B, and the second FEOL portion 32S is formed underneath the second BEOL portion 34S. In one embodiment, the second FEOL portion 32S may be configured to provide a second switch FET. The second FEOL portion 32S includes a second active layer 36S and a second contact layer 38S over the second active layer 36S. The second active layer 36S may include a second source 40S, a second drain 42S, and a second channel 44S between the second source 40S and the second drain 42S. In some applications, there might be a second body (not shown) residing underneath the second active layer 36S.

The second contact layer 38S is formed over the second active layer 36S and includes a second gate structure 46S, a second source contact 48S, a second drain contact 50S, and a second gate contact 52S. The second gate structure 46S may be formed of silicon oxide, and extends horizontally over the second channel 44S (i.e., from over the second source 40S to over the second drain 42S). The second source contact 48S is connected to and over the second source 40S, the second drain contact 50S is connected to and over the second drain 42S, and the second gate contact 52S is connected to and over the second gate structure 46S. A second insulating material 54S may be formed around the second source contact 48S, the second drain contact 50S, the second gate structure 46S, and the second gate contact 52S to electrically separate the second source 40S, the second drain 42S, and the second gate structure 46S. In different applications, the second FEOL portion 32S may have different FET configurations or provide different device components.

In addition, the second FEOL portion 32S also includes second isolation sections 56S, which reside underneath the second insulating material 54S of the second contact layer 38S and surround the second active layer 36S (and surround the second body if the second body exists, not shown). The second isolation sections 56S are configured to electrically separate the second active layer 36S from other devices (not shown) formed in the same second wafer slice 12S. Herein, the second isolation sections 56S may extend from a bottom surface of the second contact layer 38S and vertically beyond a bottom surface of the second active layer 36S to define a second opening 58S that is within the second isolation sections 56S and underneath the second active layer 36S. The second isolation sections 56S may be formed of silicon dioxide, which may be resistant to etching chemistries such as TMAH, XeF₂, KOH, NaOH, or ACH, and may be resistant to a dry etching system, such as a RIE system with a chlorine-based gas chemistry or a fluorine-based gas chemistry.

In some applications, the second active layer 36S in the second FEOL portion 32S may be passivated to achieve proper low levels of current leakage in the second device region 22S. The passivation may be accomplished with the second passivation layer 26S underneath the second FEOL portion 32S of the second device region 22S. The second passivation layer 26S may be formed of silicon oxide with a thickness between 10 nm and 5000 nm. Herein, the second passivation layer 26S may extend over an entire bottom surface of the second FEOL portion 32S, such that the second passivation layer 26S continuously covers exposed surfaces within the second opening 58S and bottom surfaces of the second isolation sections 56S. In some applications, the second passivation layer 26S may only cover a bottom surface of the second active layer 36S and resides within the second opening 58S (not shown). In some applications, the second passivation layer 26S may be omitted (not shown).

The second BEOL portion 34S is over the second FEOL portion 32S and includes multiple second connecting layers 60S formed within second dielectric layers 62S. The second connecting layers 60S may have one or more top portions not covered by the second dielectric layers 62S, such that the second top via 30B can be electrically connected to one of the uncovered top portions of the second connecting layers 60S. For the purpose of this illustration, one of the second connecting layers 60S-1 is connected to the second source contact 48S (may be used for internal connections, but not connected to the second top via 30B), and another one of the second connecting layers 60S-2 is configured to connect the second drain contact 50S to the second top via 30B. In different applications, there might be more second connecting layers 60S with a different configuration.

The second top via 30B, which extends through the second top bonding layer 16B and into the second device region 22S, is in contact with the first through-via 30A. The second top via 30B does not extend toward or into the portions of the second device region 22S where the second active layer 36S is located. The first through-via 30A and the second top via 30B may be formed of a metal material (such as copper), and are combined directly together as a first via structure 30. As such, the first switch FET provided in the first FEOL portion 32 of the first wafer slice 12 could be electrically connected to the second switch FET provided in the second FEOL portion 32S of the second wafer slice 12S through the first connecting layer 60-2, the first via structure 30, and the second connecting layer 60S-2. In different applications, the first through-via 30A and the second top via 30B may have different plane sizes and/or different vertical heights.

The second enhancement region 28S is formed underneath the second passivation layer 26S. If there is no second passivation layer 26S, the second enhancement region 28S is formed underneath the second device region 22S and extends over the entire bottom surface of the second FEOL portion 32S, such that the second enhancement region 28S continuously covers exposed surfaces within the second opening 58S and bottom surfaces of the second isolation sections 56S (not shown). If the second passivation layer 26S is only formed underneath the second active layer 36S and within the second opening 58S, the second enhancement region 28S still continuously covers exposed surfaces (including the second passivation layer 26S) within the second opening 58S and the bottom surfaces of the second isolation sections 56S (not shown). The second enhancement region 28S is configured to enhance reliability and/or thermal performance of the second device region 22S, especially the second active layer 36S in the second device region 22S.

In one embodiment, the second enhancement region 28S includes a second barrier layer 64S formed underneath the second passivation layer 26S, and a second thermally conductive layer 66S formed underneath the second barrier layer 64S. Herein, the second barrier layer 64S may be formed of silicon nitride with a thickness between 2000 Å and 10 μm. The second barrier layer 64S is configured to provide a superior barrier to moisture and impurities, which could diffuse into the second channel 44S of the second active layer 36S and cause reliability concerns in the device. Moisture, for example, may diffuse readily through a silicon oxide layer (like the second passivation layer 26S), but even a thin nitride layer (like the second barrier layer 64S) reduces the diffusion of the water molecule by several orders of magnitude, acting as an ideal barrier. In addition, the second barrier layer 64S may also be engineered so as to provide additional tensile strain to the second device region 22S. Such strain may be beneficial in providing additional improvement of electron mobility in n-channel devices. In some applications, the second barrier layer 64S formed of silicon nitride may further passivate the second active layer 36S. In such case, there may be no need for the second passivation layer 26S.

The second thermally conductive layer 66S, which may be formed of aluminum nitride with a thickness between 0.1 μm and 20 μm, could provide superior thermal dissipation for the second device region 22S, in the order of 275 W/mk while retaining superior electrically insulating characteristics. The second thermally conductive layer 66S might be very important to the overall thermal behavior of the stacked wafer slices. If power dissipation is not a concern, then the second thermally conductive layer 66S may be omitted. Due to different application needs, the entire second enhancement region 28S might be omitted, or the second barrier layer 64S might be omitted while the second thermally conductive layer 66S might be retained.

The mold compound 18 is formed underneath the second enhancement region 28S. If there is no second enhancement region 28S, the mold compound 18 is formed underneath the second passivation layer 26S and fills the second opening 58S (not shown). The heat generated in the second device region 22S (especially the second active layer 36S) may travel downward to a top portion of the mold compound 18 (through the second enhancement region 28S), especially to a portion underneath the second active layer 36S. It is therefore highly desirable for the mold compound 18 to have a high thermal conductivity, especially for a portion close to the second active layer 36S. The mold compound 18 may have a thermal conductivity between 1 W/m·K and 100 W/m·K, or between 7 W/m·K and 20 W/m·K. In addition, the mold compound 18 may have a low dielectric constant less than 8, or between 3 and 5 to yield low radio frequency (RF) coupling. The mold compound 18 may be formed of thermoplastics or thermoset polymer materials, such as polyphenylene sulfide (PPS), overmold epoxies doped with boron nitride, alumina, carbon nanotubes, or diamond-like thermal additives, or the like, and may have a thickness between 200 μm and 500 μm.

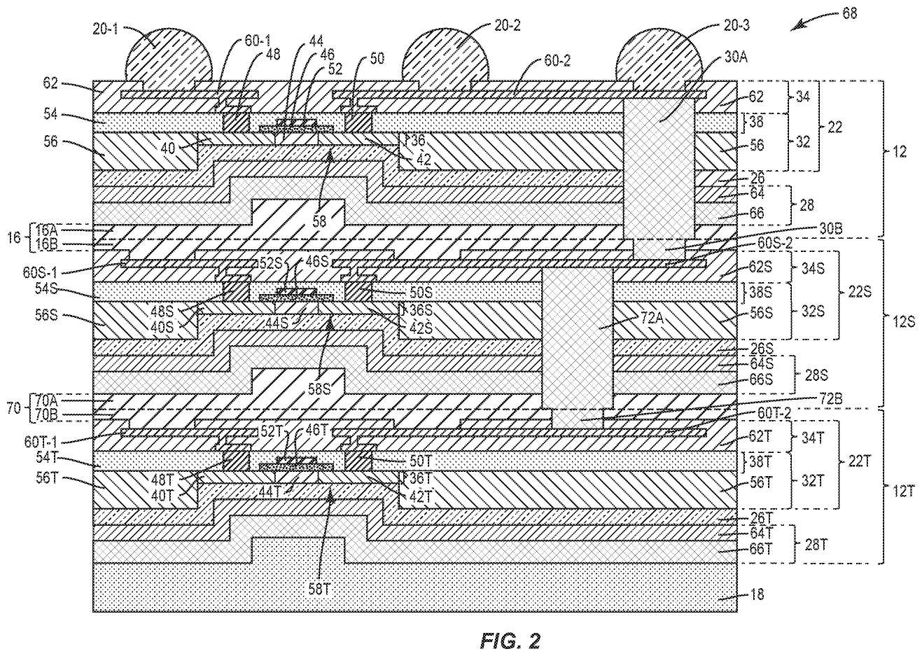

In some applications, one microelectronics package may include more than two vertically stacked wafer slices. As illustrated in FIG. 2, a second exemplary microelectronics package 68 has a vertically stacked structure of three wafer slices according to one embodiment of the present disclosure. Compared to the microelectronics package 10, the second microelectronics package 68 further includes a third wafer slice 12T vertically between the second wafer slice 12S and the mold compound 18, a second bonding region 70, and a second via structure 72.

Herein, the second wafer slice 12S and the third wafer slice 12T are bonded at the second bonding region 70, which includes a second bottom bonding layer 70A from the second wafer slice 12S and a third top bonding layer 70B from the third wafer slice 12T. In addition, the second wafer slice 12S and the third wafer slice 12T are electrically connected by the second via structure 72, which includes a second through-via 72A from the second wafer slice 12S and a third top via 72B from the third wafer slice 12T.

The second bottom bonding layer 70A may be formed of silicon oxide. If the second wafer slice 12S includes the second enhancement region 28S with the second barrier layer 64S and the second thermally conductive layer 66S, the second bottom bonding layer 70A is formed directly underneath the second thermally conductive layer 66S. If the second barrier layer 64S is retained while the second thermally conductive layer 66S is omitted, the second bottom bonding layer 70A is formed directly underneath the second barrier layer 64S (not shown). If the second barrier layer 64S is omitted while the second thermally conductive layer 66S is retained, the second bottom bonding layer 70A is formed directly underneath the second thermally conductive layer 66S (not shown). If the entire second enhancement region 28S is omitted in the second wafer slice 12S, there might not be a need for the second bottom bonding layer 70A, since the second passivation layer 26S, which is formed of silicon oxide, may also be functioned as the second bottom bonding layer for bonding to the third wafer slice 12T (not shown).

The second through-via 72A extends through the second bottom bonding layer 70A, the second enhancement region 28S, and the second passivation layer 26S, and extends into the second device region 22S. The second through-via 72A does not extend toward or into the portions of the second device region 22S where the second active layer 36S is located. The second through-via 72A (with a third top via 72B, described in following paragraphs) is configured to electrically connect the second wafer slice 12S and the third wafer slice 12T. For the purpose of this illustration, the second through-via 72A is connected to the second active layer 36S through the second connecting layer 60S-2 in the second BEOL portion 34S.

The third wafer slice 12T includes the third top bonding layer 70B at a top of the third wafer slice 12T for bonding to the second bottom bonding layer 70A, so as to bond to the second wafer slice 12S. The second bottom bonding layer 70A and the third top bonding layer 70B are formed of a same material, such as silicon oxide, and are combined directly together as the second bonding region 70. If the second wafer slice 12S does not include the second enhancement region 28S and the second bottom bonding layer 70A, the third top bonding layer 70B at the top of the third wafer slice 12T might be directly bonded to the second passivation layer 26S of the second wafer slice 12S.

Similar to the first and the second wafer slices 12 and 12S, the third wafer slice 12T also includes a third device region 22T formed underneath the third top bonding layer 70B, the third top via 72B that extends through the third top bonding layer 70B and into the third device region 22T, a third passivation layer 26T underneath the third device region 22T, and a third enhancement region 28T underneath the third passivation layer 26T.

Notice that, between the second device region 22S and the third device region 22T, there are the second bonding region 70 (the second bottom bonding layer 70A and the third top bonding layer 70B), optionally the second enhancement region 28S (the second barrier layer 64S and/or the second thermally conductive layer 66S), optionally the second passivation layer 26S, and the second via structure 72 (the second through-via 72A and the third top via 72B). In a desired case, silicon crystal (which has no germanium, nitrogen, or oxygen content) does not exist between the second device region 22S and the third device region 22T. Each of the second barrier layer 64S, the second thermally conductive layer 66S, and the second bonding region 70 is formed of silicon composite, but not silicon crystal.

The third device region 22T includes a third FEOL portion 32T and a third BEOL portion 34T. The third BEOL portion 34T is formed underneath the third top bonding layer 70B, and the third FEOL portion 32T is formed underneath the third BEOL portion 34T. In one embodiment, the third FEOL portion 32T may be configured to provide a third switch FET. The third FEOL portion 32T includes a third active layer 36T and a third contact layer 38T over the third active layer 36T. The third active layer 36T may include a third source 40T, a third drain 42T, and a third channel 44T between the third source 40T and the third drain 42T. In some applications, there might be a third body (not shown) residing underneath the third active layer 36T.

The third contact layer 38T is formed over the third active layer 36T and includes a third gate structure 46T, a third source contact 48T, a third drain contact 50T, and a third gate contact 52T. The third gate structure 46T may be formed of silicon oxide, and extends horizontally over the third channel 44T (i.e., from over the third source 40T to over the third drain 42T). The third source contact 48T is connected to and over the third source 40T, the third drain contact is connected to and over the third drain 42T, and the third gate contact 52T is connected to and over the third gate structure 46T. A third insulating material 54T may be formed around the third source contact 48T, the third drain contact the third gate structure 46T, and the third gate contact 52T to electrically separate the third source 40T, the third drain 42T, and the third gate structure 46T. In different applications, the third FEOL portion 32T may have different FET configurations or provide different device components.

In addition, the third FEOL portion 32T also includes third isolation sections 56T, which reside underneath the third insulating material 54T of the third contact layer 38T and surround the third active layer 36T (and surround the third body if the third body exists, not shown). The third isolation sections 56T are configured to electrically separate the third active layer 36T from other devices (not shown) formed in the same third wafer slice 12T. Herein, the third isolation sections 56T may extend from a bottom surface of the third contact layer 38T and vertically beyond a bottom surface of the third active layer 36T to define a third opening 58T that is within the third isolation sections 56T and underneath the third active layer 36T. The third isolation sections 56T may be formed of silicon dioxide, which may be resistant to etching chemistries such as TMAH, XeF₂, KOH, NaOH, or ACH, and may be resistant to a dry etching system, such as a RIE system with a chlorine-based gas chemistry or a fluorine-based gas chemistry.

In some applications, the third active layer 36T in the third FEOL portion 32T may be passivated to achieve proper low levels of current leakage in the third device region 22T. The passivation may be accomplished with the third passivation layer 26T underneath the third FEOL portion 32T of the third device region 22T. The third passivation layer 26T may be formed of silicon oxide with a thickness between 10 nm and 5000 nm. Herein, the third passivation layer 26T may extend over an entire bottom surface of the third FEOL portion 32T, such that the third passivation layer 26T continuously covers exposed surfaces within the third opening 58T and bottom surfaces of the third isolation sections 56T. In some applications, the third passivation layer 26T may only cover a bottom surface of the third active layer 36T and resides within the third opening 58T (not shown). In some applications, the third passivation layer 26T may be omitted (not shown).

The third BEOL portion 34T is over the third FEOL portion 32T and includes multiple third connecting layers 60T formed within third dielectric layers 62T. The third connecting layers 60T may have one or more top portions not covered by the third dielectric layers 62T, such that the third top via 72B can be electrically connected to one of the uncovered top portions of the third connecting layers 60T. For the purpose of this illustration, one of the third connecting layers 60T-1 is connected to the third source contact 48T (may be used for internal connections, but not connected to the third top via 72B), and another one of the third connecting layers 60T-2 is configured to connect the third drain contact 50T to the third top via 72B. In different applications, there might be more third connecting layers 60T with a different configuration.

The third top via 72B, which extends through the third top bonding layer 70B and into the third device region 22T, is in contact with the second through-via 72A. The third top via 72B does not extend toward or into the portions of the third device region 22T where the third active layer 36T is located. The second through-via 72A and the third top via 72B may be formed of a metal material (such as copper), and are combined directly together as a second via structure 72. As such, the second switch FET provided in the second FEOL portion 32S of the second wafer slice 12S could be electrically connected to the third switch FET provided in the third FEOL portion 32T of the third wafer slice 12T through the second connecting layer 60S-2, the second via structure 72, and the third connecting layer 60T-2. In different applications, the second through-via 72A and the third top via 72B may have different plane sizes and/or different vertical heights.

The third enhancement region 28T is formed underneath the third passivation layer 26T. If there is no third passivation layer 26T, the third enhancement region 28T is formed underneath the third device region 22T and extends over the entire bottom surface of the third FEOL portion 32T, such that the third enhancement region 28T continuously covers exposed surfaces within the third opening 58T and bottom surfaces of the third isolation sections 56T (not shown). If the third passivation layer 26T is only formed underneath the third active layer 36T and within the third opening 58T, the third enhancement region 28T still continuously covers exposed surfaces (including the third passivation layer 26T) within the third opening 58T and the bottom surfaces of the third isolation sections 56T (not shown). The third enhancement region 28T is configured to enhance reliability and/or thermal performance of the third device region 22T, especially the third active layer 36T in the third device region 22T.

In one embodiment, the third enhancement region 28T includes a third barrier layer 64T formed underneath the third passivation layer 26T, and a third thermally conductive layer 66T formed underneath the third barrier layer 64T. Herein, the third barrier layer 64T may be formed of silicon nitride with a thickness between 2000 Å and 10 μm. The third barrier layer 64T is configured to provide a superior barrier to moisture and impurities, which could diffuse into the third channel 44T of the third active layer 36T and cause reliability concerns in the device. Moisture, for example, may diffuse readily through a silicon oxide layer (like the third passivation layer 26T), but even a thin nitride layer (like the third barrier layer 64T) reduces the diffusion of the water molecule by several orders of magnitude, acting as an ideal barrier. In addition, the third barrier layer 64T may also be engineered so as to provide additional tensile strain to the third device region 22T. Such strain may be beneficial in providing additional improvement of electron mobility in n-channel devices. In some applications, the third barrier layer 64T formed of silicon nitride may further passivate the third active layer 36T. In such case, there may be no need for the third passivation layer 26T.

The third thermally conductive layer 66T, which may be formed of aluminum nitride with a thickness between 0.1 μm and 20 μm, could provide superior thermal dissipation for the third device region 22T, in the order of 275 W/mk while retaining superior electrically insulating characteristics. The third thermally conductive layer 66T might be very important to the overall thermal behavior of the stacked wafer slices. If power dissipation is not a concern, then the third thermally conductive layer 66T may be omitted. Due to different application needs, the entire third enhancement region 28T might be omitted, or the third barrier layer 64T might be omitted while the third thermally conductive layer 66T might be retained.

In the second microelectronics package 68, the mold compound 18 is formed underneath the third enhancement region 28T of the third wafer slice 12T. If there is no third enhancement region 28T, the mold compound 18 is formed underneath the third passivation layer 26T and fills the third opening 58T (not shown). The heat generated in the third device region 22T (especially the third active layer 36T) may travel downward to a top portion of the mold compound 18 (through the third enhancement region 28T), especially to a portion underneath the third active layer 36T. It is therefore highly desirable for the mold compound 18 to have a high thermal conductivity, especially for a portion close to the third active layer 36T. The mold compound 18 may have a thermal conductivity between 1 W/m-K and 100 W/m-K, or between 7 W/m-K and 20 W/m·K. In addition, the mold compound 18 may have a low dielectric constant less than 8, or between 3 and 5 to yield low RF coupling. The mold compound 18 may be formed of thermoplastics or thermoset polymer materials, such as PPS, overmold epoxies doped with boron nitride, alumina, carbon nanotubes, or diamond-like thermal additives, or the like, and may have a thickness between 200 μm and 500 μm.

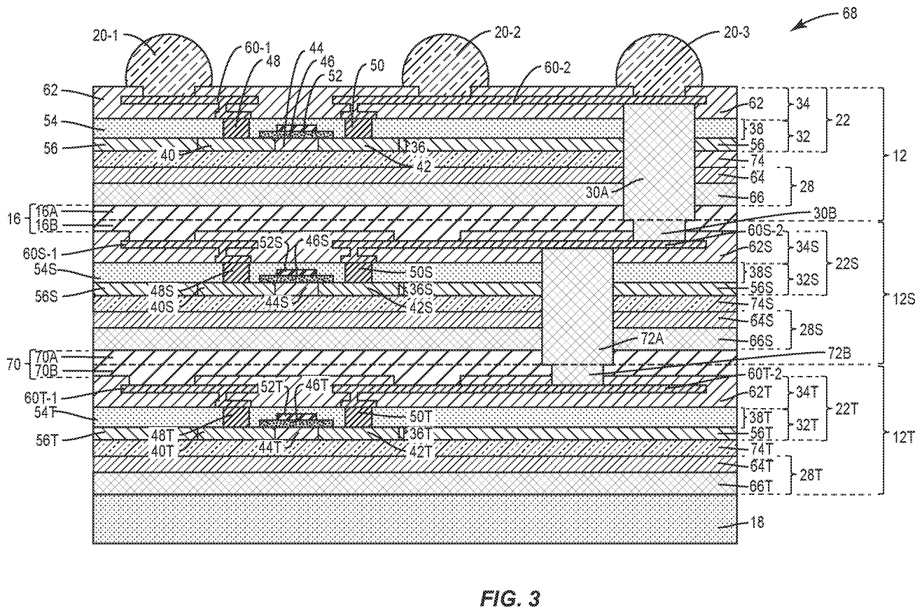

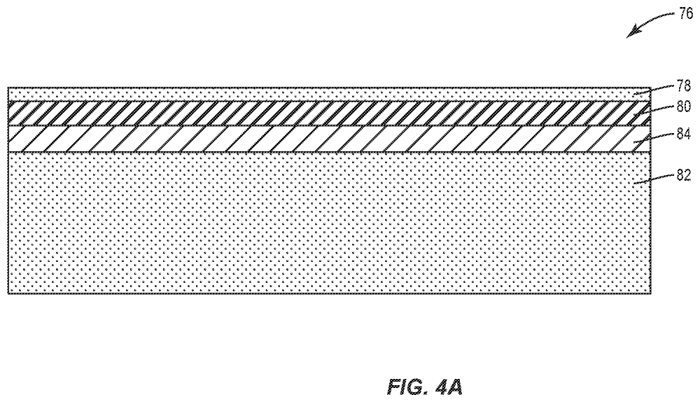

In some applications, each of the first, second and third wafer slices 12, 12S, and 12T is formed from a silicon-on-insulator (SOI) complementary metal-oxide-semiconductor (CMOS) wafer slice, which includes a silicon epitaxy layer, a silicon substrate, and a buried oxide (BOX) layer sandwiched between the silicon epitaxy layer and the silicon substrate (not shown). Each of the first device region 22 in the first wafer slice 12, the second device region 22S in the second wafer slice 12S, and the third device region 22T in the third wafer slice 12T is formed by fabricating device elements in or on the silicon epitaxy layer of the SOI CMOS wafer slice, and resides over an oxide layer (74/74S/74T) that is the BOX layer of the SOI CMOS wafer, as illustrated in FIG. 3.

In this embodiment, the first active layer 36 and the first isolation sections 56 are formed over a first oxide layer 74, and the bottom surface of each first isolation section 56 does not extend vertically beyond the bottom surface of the first active layer 36, such that the first opening 58 is omitted. The first active layer 36 does not need an extra passivation layer (e.g., the first passivation layer 26), since the first oxide layer 74 (which is formed of silicon oxide and formed underneath the first active layer 36) passivates the first active layer 36. The first oxide layer 74 continuously covers the bottom surface of the first active layer 36 and bottom surfaces of the first isolation sections 56, and the first enhancement region 28 is formed underneath the first oxide layer 74.

Similarly, the second active layer 36S and the second isolation sections 56S are formed over a second oxide layer 74S, and the bottom surface of each second isolation section 56S does not extend vertically beyond the bottom surface of the second active layer 36S, such that the second opening 58S is omitted. The second active layer 36S does not need an extra passivation layer (e.g., the second passivation layer 26S), since the second oxide layer 74S (which is formed of silicon oxide and formed underneath the second active layer 36S) passivates the second active layer 36S. The second oxide layer 74S continuously covers the bottom surface of the second active layer 36S and bottom surfaces of the second isolation sections 56S, and the second enhancement region 28S is formed underneath the second oxide layer 74S.

The third active layer 36T and the third isolation sections 56T are formed over a third oxide layer 74T, and the bottom surface of each third isolation section 56T does not extend vertically beyond the bottom surface of the third active layer 36T, such that the third opening 58T is omitted. The third active layer 36T does not need an extra passivation layer (e.g., the third passivation layer 26T), since the third oxide layer 74T (which is formed of silicon oxide and formed underneath the third active layer 36T) passivates the third active layer 36T. The third oxide layer 74T continuously covers the bottom surface of the third active layer 36T and bottom surfaces of the third isolation sections 56T, and the third enhancement region 28T is formed underneath the third oxide layer 74T.

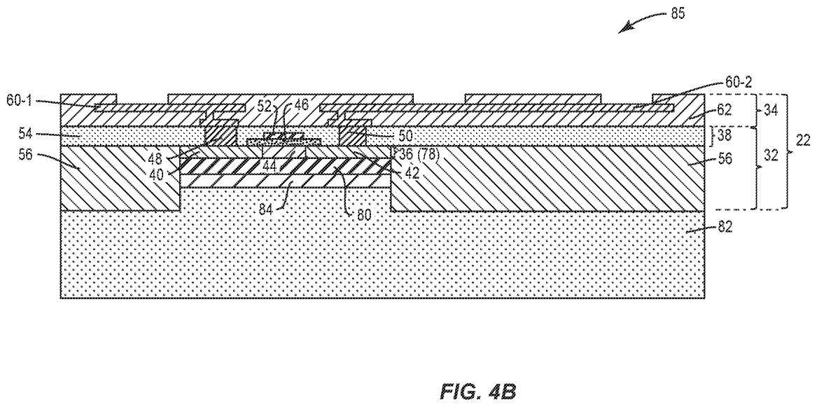

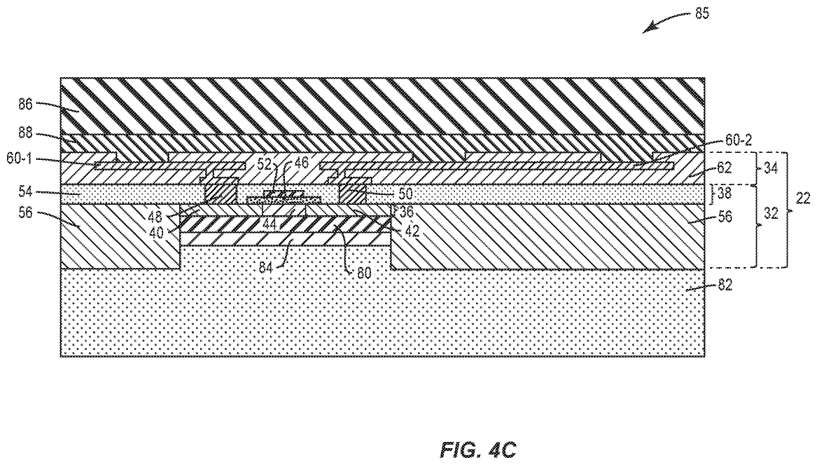

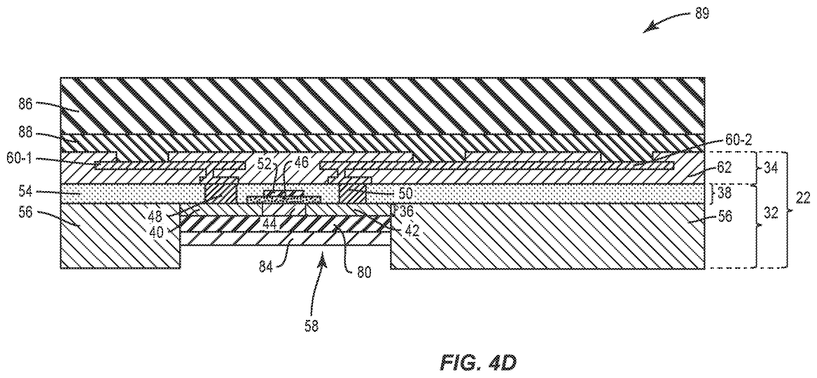

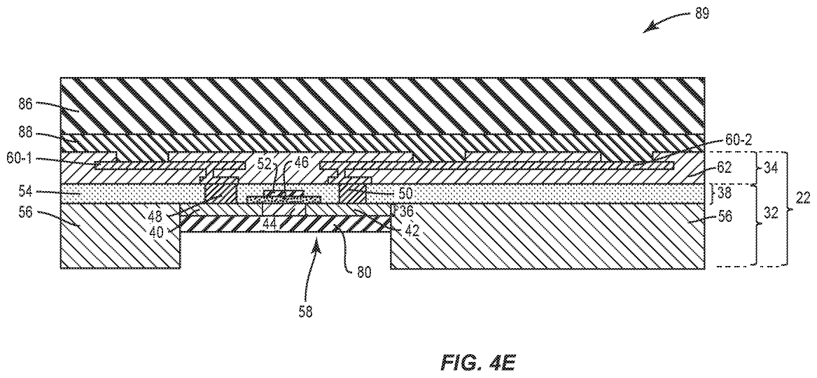

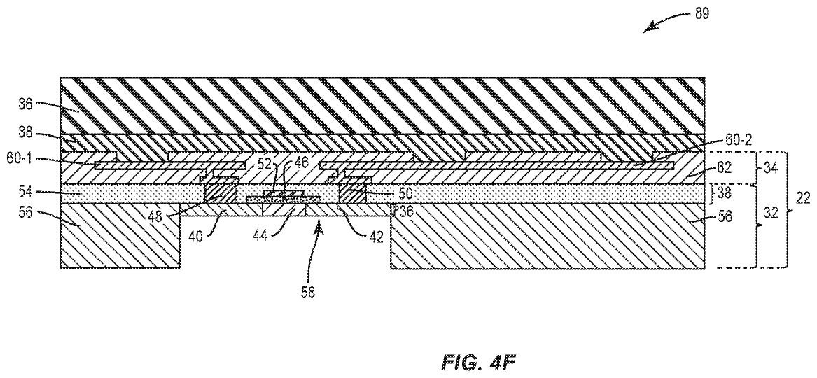

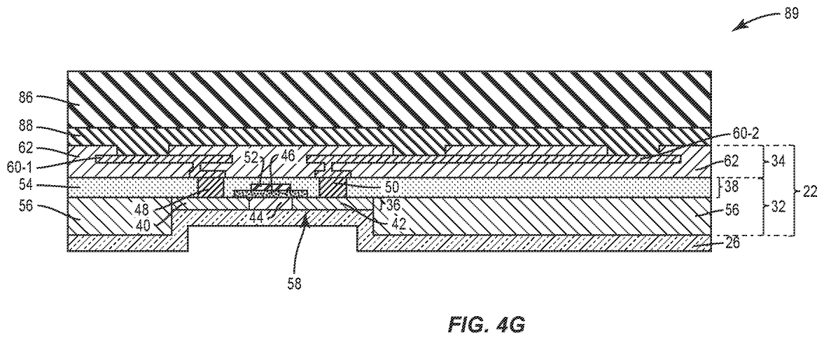

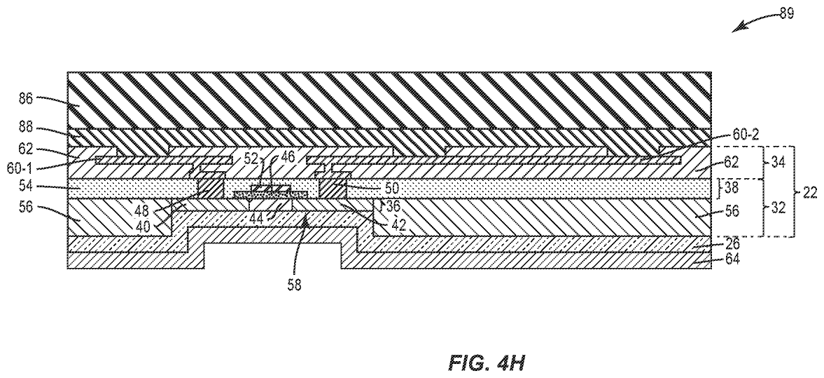

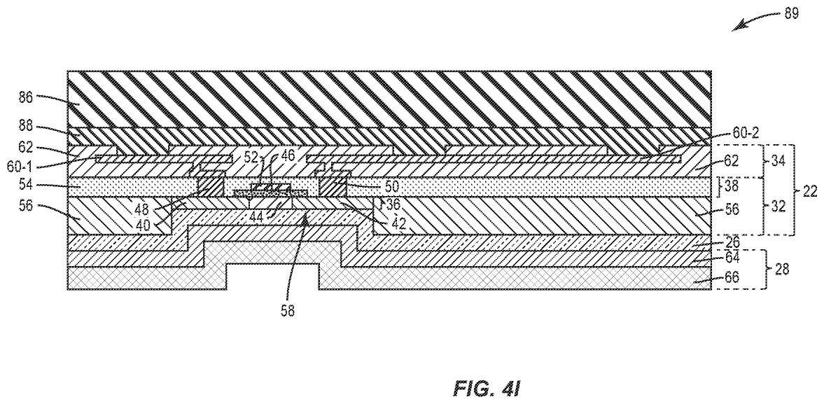

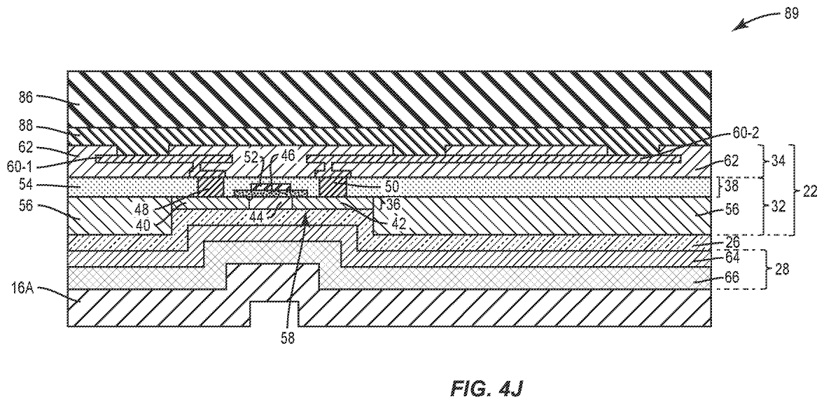

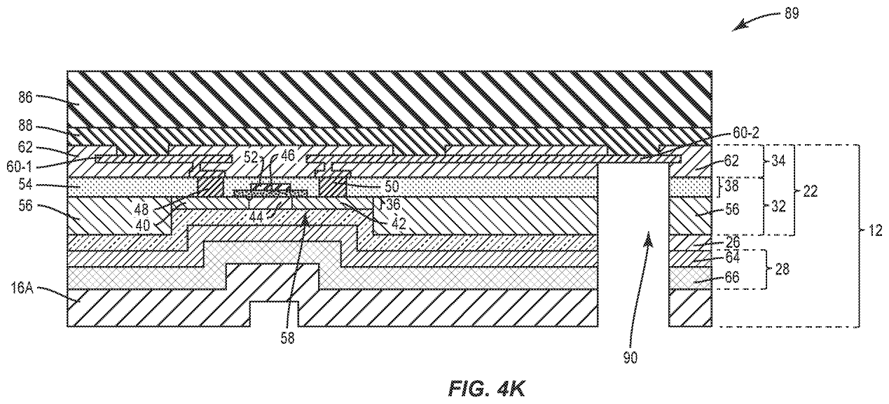

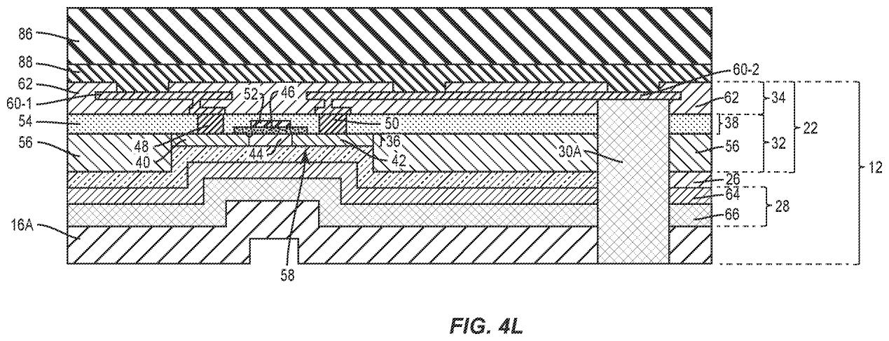

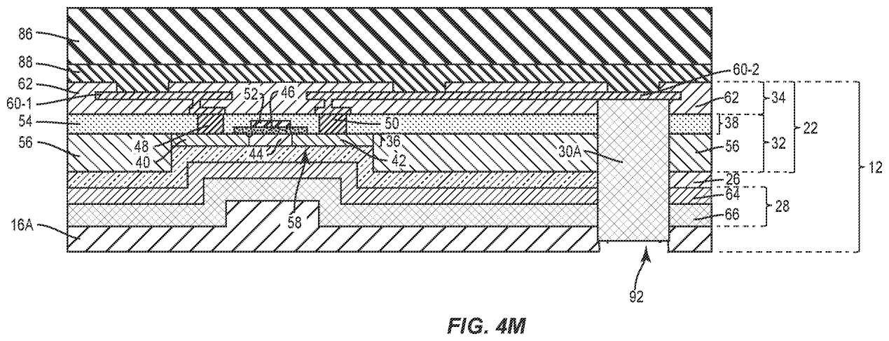

FIGS. 4A-15 provide an exemplary wafer-level fabricating and packaging process that illustrates steps to manufacture the microelectronics package 10 shown in FIG. 1. Although the exemplary steps are illustrated in a series, the exemplary steps are not necessarily order dependent. Some steps may be done in a different order than that presented. Further, processes within the scope of this disclosure may include fewer or more steps than those illustrated in FIGS. 4A-15.

With reference to FIGS. 4A through 4M, the first wafer 12, which includes the first device region 22, is prepared for the microelectronics package 10. Initially, a first starting wafer slice 76 is provided as illustrated in FIG. 4A. The first starting wafer slice 76 includes a first silicon epitaxial layer 78, a first interfacial layer 80 underneath the first silicon epitaxial layer 78, and a first silicon handle substrate 82 underneath the first interfacial layer 80. Herein, the first silicon epitaxial layer 78 is formed from a device grade silicon material, which has desirable silicon epitaxy characteristics to form electronic devices. The first silicon handle substrate 82 may consist of conventional low cost, low resistivity, and high dielectric constant silicon, which may have a lattice constant about at a temperature of 300K. The first interfacial layer 80 is formed of SiGe, which separates the first silicon epitaxial layer 78 from the first silicon handle substrate 82.

At a fixed temperature, e.g., 300K, a lattice constant of relaxed silicon is 5.431 Å, while a lattice constant of relaxed Si₁₋ₓGeₓ depends on the germanium concentration, such as (5.431+0.2x+0.027x²) Å. The lattice constant of relaxed SiGe is larger than the lattice constant of relaxed silicon. If the first interfacial layer 80 is directly grown over the first silicon handle substrate 82, the lattice constant in the first interfacial layer 80 will be strained (reduced) by the first silicon handle substrate 82. And if the first silicon epitaxial layer 78 is directly grown over the strained first interfacial layer 80, the lattice constant in the first silicon epitaxial layer 78 may remain as the original relaxed form (about the same as the lattice constant in the first silicon substrate 82). Consequently, the first silicon epitaxial layer 78 may not enhance electron mobility.

In one embodiment, a first buffer structure 84 may be formed between the first silicon handle substrate 82 and the first interfacial layer 80. The first buffer structure 84 allows a lattice constant transition from the first silicon handle substrate 82 to the first interfacial layer 80. The first buffer structure 84 may include multiple layers and may be formed of SiGe with a vertically graded germanium concentration. The germanium concentration within the first buffer structure 84 may increase from 0% at a bottom side (next to the first silicon handle substrate 82) to X % at a top side (next to the first interfacial layer 80). The X % may depend on the germanium concentration within the first interfacial layer such as 15%, or 25%, or 30%, or 40%. The first interfacial layer 80, which herein is grown over the first buffer structure 84, may keep its lattice constant in relaxed form, and may not be strained (reduced) to match the lattice constant of the first silicon handle substrate 82. The germanium concentration may be uniform throughout the first interfacial layer 80 and greater than 15%, 25%, 30%, or 40%, such that the lattice constant of relaxed SiGe in the first interfacial layer 80 is greater than 5.461, or greater than 5.482, or greater than 5.493, or greater than 5.515 at a temperature of 300K.

Herein, the first silicon epitaxial layer 78 is grown directly over the relaxed first interfacial layer 80, such that the first silicon epitaxial layer 78 has a lattice constant matching (stretching as) the lattice constant in the relaxed first interfacial layer 80. Consequently, the lattice constant in the strained first silicon epitaxial layer 78 may be greater than 5.461, or greater than 5.482, or greater than 5.493, or greater than 5.515 at a temperature of 300K, and therefore greater than the lattice constant in a relaxed silicon epitaxial layer (e.g., 5.431 at a temperature of 300K). The strained first silicon epitaxial layer 78 may have a higher electron mobility than a relaxed silicon epitaxial layer. A thickness of the first silicon epitaxial layer 78 may be between 700 nm and 2000 nm, a thickness of the first interfacial layer 80 may be between 200 Å and 600 Å, a thickness of the first buffer structure 84 may be between 100 nm and 1000 nm, and a thickness of the first silicon handle substrate 82 may be between 200 μm and 700 μm.

In some applications, the first buffer structure 84 is omitted (not shown). The first interfacial layer 80 is grown directly over the first silicon handle substrate 82 and the first silicon epitaxial layer 78 is grown directly over the first interfacial layer 80. As such, the lattice constant in the first interfacial layer 80 is strained (reduced) to match the lattice constant in the first silicon handle substrate 82, and the lattice constant in the first silicon epitaxial layer 78 remains as the original relaxed form (about the same as the lattice constant in the first silicon substrate 82).

Next, a CMOS process is performed on the first starting wafer slice 76 to provide a first precursor wafer slice 85, which includes the first device regions 22 with the first FEOL portion 32 and the first BEOL portion 34, as illustrated in FIG. 4B. For the purpose of this illustration, the first FEOL portion 32 of the first device region 22 is configured to provide the first switch FET. In different applications, the first FEOL portion 32 may have different FET configurations or provide different device components, such as a diode, a capacitor, a resistor, and/or an inductor.

The first BEOL portion 34 is formed over the first FEOL portion 32 and includes the first connecting layers 60 formed within the first dielectric layers 62. The first connecting layers 60 may have one or more top portions not covered by the first dielectric layers 62, such that the first connecting layers 60 are eligible to be electrically connected to external components not within the first precursor wafer slice 85.

The first FEOL portion 32 includes the first active layer 36, the first contact layer 38 over the first active layer 36, and the first isolation sections 56. The first active layer 36 is formed from the first silicon epitaxial layer 78, and may include the first source 40, the first drain 42, and the first channel 44 between the first source 40 and the first drain 42. The first contact layer 38, which is formed underneath the first BEOL portion 34 and over the first active layer 36, is configured to connect the first active layer 36 to the first BEOL portion 34. The first contact layer 38 includes the first gate structure 46, the first source contact 48, the first drain contact 50, and the first gate contact 52. The first gate structure 46 may be formed of silicon oxide, and extends horizontally over the first channel 44 (i.e., from over the first source 40 to over the first drain 42). The first source contact 48 is connected to and over the first source 40, the first drain contact 50 is connected to and over the first drain 42, and the first gate contact 52 is connected to and over the first gate structure 46. The first insulating material 54 may be formed around the first source contact 48, the first drain contact 50, the first gate structure 46, and the first gate contact 52 to electrically separate the first source 40, the first drain 42, and the first gate structure 46. For the purpose of this illustration, one of the first connecting layers 60-1 in the first BEOL portion 34 is connected to the first source contact 48 and another one of the first connecting layers 60-2 of the first BEOL portion 34 is connected to the first drain contact 50. In different applications, the first FEOL portion 32 may have different FET configurations or provide different device components.

The first isolation sections 56 extend from the bottom surface of the first contact layer 38, through the first silicon epitaxial layer 78, the first interfacial layer 80, and the first buffer structure 84, and extend into the first silicon handle substrate 82. As such, the first isolation sections 56 surround the remaining first silicon epitaxial layer 78 (the first active layer 36), the remaining first interfacial layer 80, and the remaining first buffer structure 84. The first isolation sections 56 may be formed by shallow trench isolation (STI). Herein, if the first active layer 36 is formed from the first silicon epitaxial layer 78 with a strained (increased) lattice constant, the first FET based on the first active layer 36 may have a faster switching speed (lower ON-resistance) than a FET formed from a relaxed silicon epitaxial layer with a relaxed lattice constant. The first isolation sections 56 may be formed of silicon dioxide, which may be resistant to etching chemistries such as TMAH, XeF₂, KOH, NaOH, or ACH, and may be resistant to a dry etching system, such as a RIE system with a chlorine-based gas chemistry.

The first interfacial layer 80 may be directly underneath the first active layer 36, and the first buffer structure 84 remains underneath the first interfacial layer 80. The first silicon handle substrate 82 remains underneath the first buffer structure 84, and portions of the first silicon handle substrate 82 may reside underneath the first isolation sections 56. As such, the first interfacial layer 80/the first buffer structure 84 and the first isolation sections 56 separate the first active layer 36 from the first silicon handle substrate 82.

Next, the first precursor wafer slice 85 is then attached to a temporary carrier 86, as illustrated in FIG. 4C. The first precursor wafer slice 85 may be attached to the temporary carrier 86 via an attaching layer 88, which provides a planarized surface to the temporary carrier 86. The temporary carrier 86 may be a thick silicon wafer from a cost and thermal expansion point of view, but may also be constructed of glass, sapphire, or any other suitable carrier material. The attaching layer 88 may be a span-on polymeric adhesive film, such as the Brewer Science WaferBOND line of temporary adhesive materials.

The first silicon handle substrate 82 is then selectively removed to provide a first etched wafer slice 89, as illustrated in FIG. 4D. The selective removal may stop at the first isolation sections 56 and the first buffer structure 84. Since the first isolation sections 56 extend vertically beyond the first buffer structure 84, the removal of the first silicon handle substrate 82 will provide the first opening 58 underneath the first active layer 36 and within the first isolation sections 56. Removing the first silicon handle substrate 82 may be provided by a mechanical grinding process and an etching process or provided by the etching system itself. As an example, the first silicon handle substrate 82 may be ground to a thinner thickness to reduce the following etching time. An etching process is then performed to at least completely remove the remaining first silicon handle substrate 82. Since the first silicon handle substrate 82, the first buffer structure 84, and the first interfacial layer 80 have different germanium concentrations, they may have different reactions to a same etching technique (for instance: different etching speeds with a same etchant). Consequently, the etching system may be capable of identifying the presence of the first buffer structure 84 or the first interfacial layer 80 (presence of germanium), and capable of indicating when to stop the etching process. Typically, the higher the germanium concentration, the better the etching selectivity between the first silicon handle substrate 82 and the first buffer structure 84 (or between the first silicon handle substrate 82 and the first interfacial layer 80). The etching process may be provided by a wet etching system with an etchant chemistry, which is at least one of TMAH, KOH, NaOH, ACH, and XeF2, or a dry etching system, such as a reactive ion etching system with a chlorine-based gas chemistry. During the removal process, the first isolation sections 56 are not removed and protect sides of the first active layer 36. The attaching layer 88 and the temporary carrier 86 protect the first device region 22.

Due to the narrow gap nature of the SiGe material, it is possible that the first buffer structure 84 and/or the first interfacial layers 80 may be conductive (for some type of devices). The first buffer structure 84 and/or the first interfacial layers 80 may cause appreciable leakage between the first source 40 and the first drain 42 of the first active layer 36. Therefore, in some applications, such as FET switch applications, it is desirable to also remove the first buffer structure 84 and the first interfacial layers 80, as illustrated in FIGS. 4E and 4F. The first active layer 36 is exposed in the first opening 58. The first buffer structure 84 and the first interfacial layer 80 may be removed by the same etching process used to remove the first silicon handle substrate 82, or may be removed by another etching process, such as a chlorine-based dry etching system (Chlorine or fluorine-based) and/or a wet etching (using TMAH, NH4OH:H2O2, H2O2, etc.). Herein, if the first interfacial layer 80 is thin enough, it may not cause any appreciable leakage between the first source 40 and the first drain 42 of the first FEOL portion 32. In that case, the first interfacial layer 80 may be left (not shown).

In some applications, after the removal of the first silicon handle substrate 82, the first buffer structure 84, and the first interfacial layer 80, the first active layer 36 may be passivated to achieve further low levels of current leakage in the device. The first passivation layer 26 may be formed directly underneath the first FEOL portion 32 of the first device region 22, as illustrated in FIG. 4G. Herein, the first passivation layer 26 may extend over the entire bottom surface of the first FEOL portion 32, such that the first passivation layer 26 continuously covers exposed surfaces within the first opening 58 and the bottom surfaces of the first isolation sections 56. In some applications, the first passivation layer 26 may only cover the bottom surface of the first active layer 36 and resides within the first opening 58 without covering the bottom surfaces of the first isolation sections 56 (not shown). The first passivation layer 26 may be formed of silicon oxide by a plasma enhanced deposition process, an anodic oxidation process, an ozone-based oxidation process, and a number of other proper techniques.

Next, the first barrier layer 64 is applied directly underneath the first passivation layer 26, as illustrated in FIG. 4H. The first barrier layer 64 is configured to provide a superior barrier to moisture and impurities, which could diffuse into the first channel 44 of the first active layer 36 and cause reliability concerns in the device. In addition, the first barrier layer 64 may also be engineered so as to provide additional tensile strain to the first device region 22. Such strain may be beneficial in providing additional improvement of electron mobility in n-channel devices. If the first passivation layer 26 is formed only with the first opening 58, the first barrier layer 64 continuously covers exposed surfaces within the first opening 58 (at the bottom surface of the first passivation layer 26 and side surface portions of the first isolation sections 56) and bottom surfaces of the first isolation sections 56 (not shown). In some applications, the first barrier layer 64, which is formed of silicon nitride with a thickness between 2000 Å and 10 μm, may further passivate the first active layer 36. In such case, there may be no need for the first passivation layer 26. The first barrier layer 64 always extends over the bottom surface of the first active layer 36. The first barrier layer 64 may be formed by a chemical vapor deposition system such as a plasma-enhanced chemical vapor deposition (PECVD) system, or an atomic layer deposition (ALD) system, such as a PEALD system.

The first thermally conductive layer 66 is then applied underneath the first barrier layer 64 to form the first enhancement region 28, as illustrated in FIG. 4I. The first thermally conductive layer 66, which may be formed of aluminum nitride with a thickness between 0.1 μm and 20 μm, is configured to provide superior thermal dissipation for the first device region 22, in the order of 275 W/mk while retaining superior electrically insulating characteristics. The first thermally conductive layer 66 might be very important to the overall thermal behavior of the stacked wafer slices. If power dissipation is not of a concern, then the first thermally conductive layer 66 may be omitted. The first thermally conductive layer 66 may be formed by chemical vapor deposition (CVD), ALD, or other similar methods known to those skilled in the art of semiconductor processing.

If the first enhancement region 28 is applied underneath the first passivation layer 26, it is necessary to add the first bottom bonding layer 16A underneath the first enhancement region 28, as illustrated in FIG. 4J. The first bottom bonding layer 16A is configured to be used at a later part of the process to connect to another wafer slice. The first bottom bonding layer 16A may be formed of silicon oxide, and is engineered to have a proper thickness for subsequent planarization and bonding steps. If the entire first enhancement region 28 is omitted, there might not be a need for the first bottom bonding layer 16A, since the first passivation layer 26 may also be used for bonding to the other wafer slice.

Next, a first through-via cavity 90 is formed through the first bottom bonding layer 16A, the first enhancement region 28, and the first passivation layer 26, and extends into the first device region 22 to expose a bottom surface portion of one of the first connecting layer 60-2, as illustrated in FIG. 4K. The first through-via cavity 90 does not extend through or into the portions of the first device region 22 where the first active layer 36 is located. The first through-via cavity 90 may have a shape of a cuboid, a polygon, a cylinder, or a cone and has a depth greater than a thickness combination of the first bottom bonding layer 16A, the first enhancement region 28, and the first passivation layer 26. The first through-via cavity 90 may be formed by a photo masking process and an etching process. The etching process is designed to be selective to metals, which means the etching process proceeds (removing portions of the first bottom bonding layer 16A, portions of the first enhancement region 28, and portions of the first passivation layer 26) until the first connecting layer 60-2 is reached.

The first through-via 30A is then formed in the first through-via cavity 90 to complete the first wafer slice 12, as illustrated in FIG. 4L. The first through-via 30A may be formed by filling the first through-via cavity 90 with one or more appropriate materials. The appropriate material is required to be electrically conductive, such as platinum, gold, silver, copper, aluminum, tungsten, titanium, electrically conductive epoxy, or other suitable materials. For defect-free and void-free wafer slice bonding, a backside of the first wafer slice 12 needs to be planarized with a nano-meter range flatness. Chemical mechanical polishing (CMP) technology may be utilized in the planarization process. Since the backside of the first wafer slice 12 contains regions of both silicon oxide (the first bottom bonding layer 16A) and electrically conductive material (the first through-via 30A), a combination of different CMP slurries and wheels may be necessary. If the first through-via 30A is formed of copper and will be bonded to another copper via using hybrid copper-copper bonding, it is desirable that the first through-via 30A be recessed by an appropriate amount compared to the first bottom bonding layer 16A, as illustrated in FIG. 4M. Such recess 92 (from a planarized bottom surface of the first bottom bonding layer 16A to a planarized bottom surface of the first through-via has a depth between 0.2 nm and 200 nm. This can be accomplished with a proper choice of copper/oxide slurries.

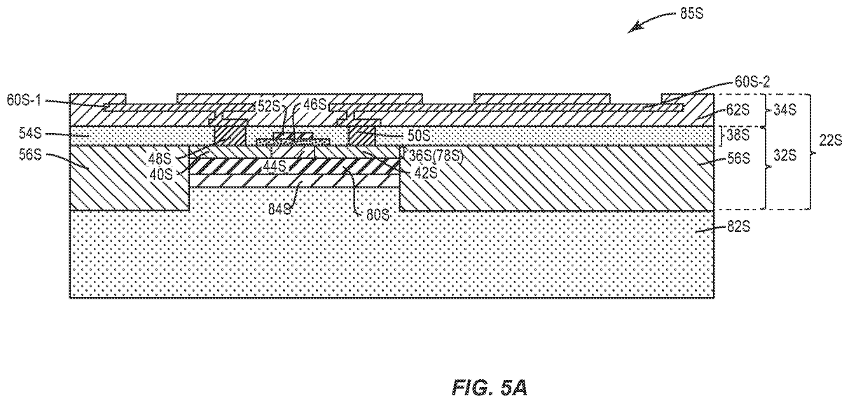

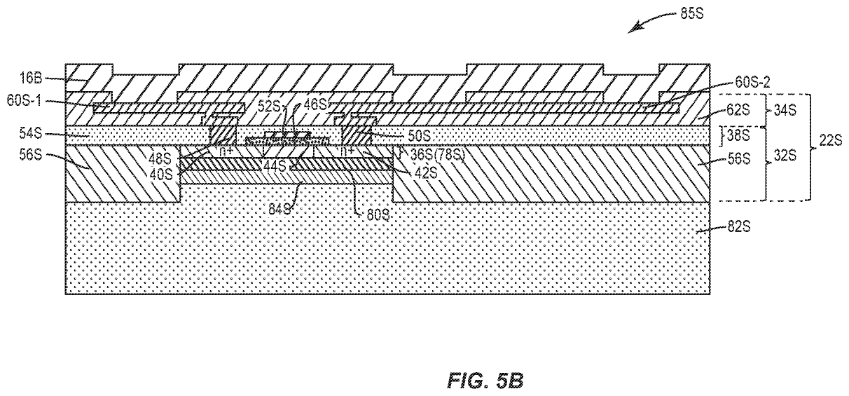

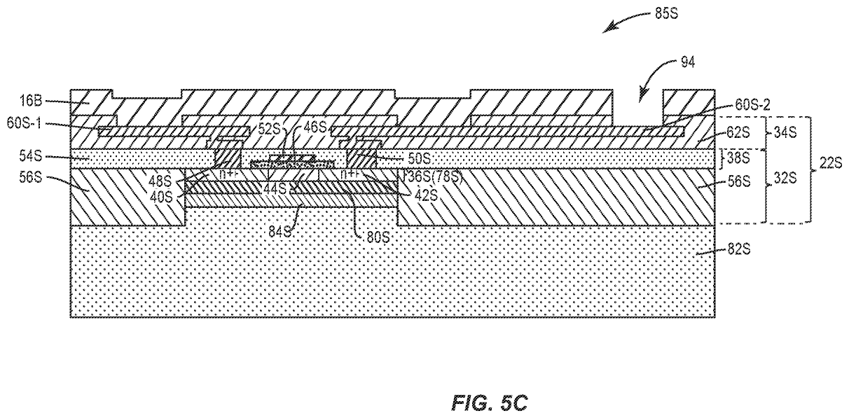

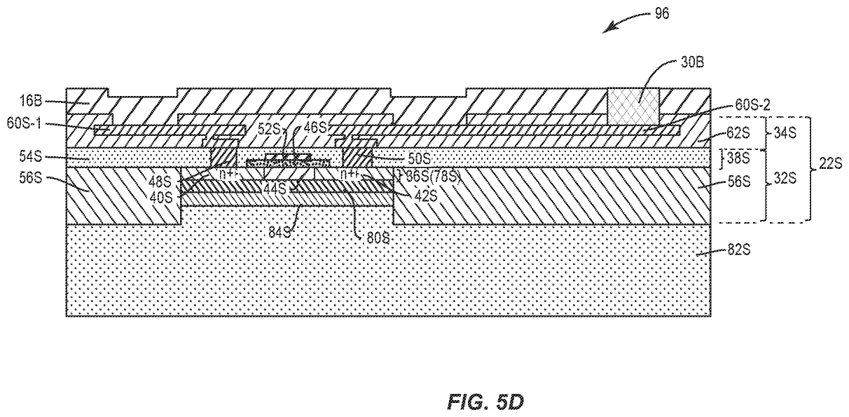

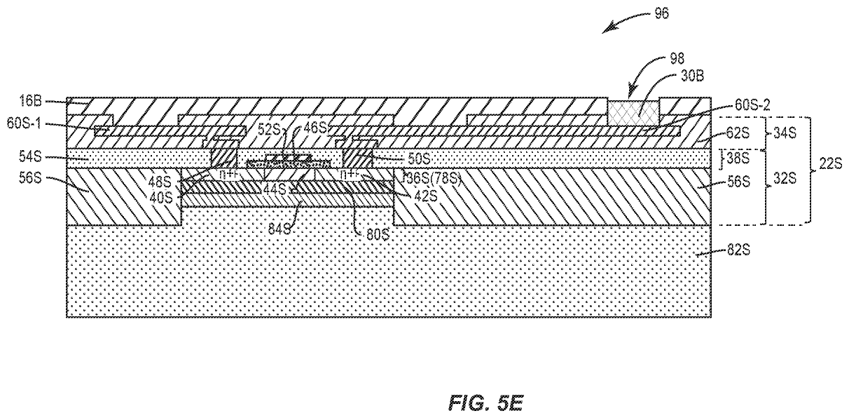

With reference to FIGS. 5A through 5E, a bonding-ready wafer slice, which includes the second device region 22S, is prepared for the microelectronics package 10. Similar to the first precursor wafer slice 85, a second precursor wafer slice 85S is provided as illustrated in FIG. 5A. The second precursor wafer slice 85S includes the second device region 22S with the second FEOL portion 32S and the second BEOL portion 34S, a second interfacial layer 80S, a second buffer structure 84S, and a second silicon handle substrate 82S.

The second BEOL portion 34S is formed over the second FEOL portion 32S and includes the second connecting layers 60S formed within the second dielectric layers 62S. The second connecting layers 60S may have one or more top portions not covered by the second dielectric layers 62S, such that the second connecting layers 60S may be electrically connected to external components not within the second precursor wafer slice 85S.

The second FEOL portion 32S, which may be configured to provide the second switch FET, includes the second active layer 36S and the second contact layer 38S. The second active layer 36S is formed from a second silicon epitaxial layer 78S, and may include the second source 40S, the second drain 42S, and the second channel 44S between the second source 40S and the second drain 42S. The second contact layer 38S, which is formed underneath the second BEOL portion 34S and over the second active layer 36S, is configured to connect the second active layer 36S to the second BEOL portion 34S. The second contact layer 38S includes the second gate structure 46S, the second source contact 48S, the second drain contact 50S, and the second gate contact 52S. The second gate structure 46S may be formed of silicon oxide, and extends horizontally over the second channel 44S (i.e., from over the second source 40S to over the second drain 42S). The second source contact 48S is connected to and over the second source 40S, the second drain contact 50S is connected to and over the second drain 42S, and the second gate contact 52S is connected to and over the second gate structure 46S. The second insulating material 54S may be formed around the second source contact 48S, the second drain contact 50S, the second gate structure 46S, and the second gate contact 52S to electrically separate the second source 40S, the second drain 42S, and the second gate structure 46S. For the purpose of this illustration, one of the second connecting layers 60S-1 in the second BEOL portion 34S is connected to the second source contact 48S and another one of the second connecting layers 60S-2 of the second BEOL portion 34S is connected to the second drain contact 50S. In different applications, the second FEOL portion 32S may have different FET configurations or provide different device components.

In addition, the second FEOL portion 32S also includes the second isolation sections 56S, which reside underneath the second insulating material 54S of the second contact layer 38S. The second isolation sections 56S extend from the bottom surface of the second contact layer 38S, through the second silicon epitaxial layer 78S, the second interfacial layer 80S, and the second buffer structure 84S, and extend into the second silicon handle substrate 82S. Herein, the second active layer 36S is fabricated from the second silicon epitaxial layer 78S, and the second silicon epitaxial layer 78S, the second interfacial layer 80S, the second buffer structure 84S, and the second silicon handle substrate 82S are provided by a starting wafer slice, which has a similar/same configuration and materials as the first starting wafer slice 76. As such, the second isolation sections 56S surround the second active layer 36S, the remaining second interfacial layer 80S, and the remaining second buffer structure 84S. The second isolation sections 56S are configured to electrically separate the second active layer 36S from other devices formed in the same second precursor wafer slice (not shown). The second isolation sections 56S may be formed by STI. The second isolation sections 56S may be formed of silicon dioxide, which may be resistant to etching chemistries such as TMAH, XeF₂, KOH, NaOH, or ACH, and may be resistant to a dry etching system, such as a RIE system with a chlorine-based gas chemistry.

The second interfacial layer 80S may be directly underneath the second active layer 36S, and the second buffer structure 84S remains underneath the second interfacial layer 80S. The second silicon handle substrate 82S remains underneath the second buffer structure 84S, and portions of the second silicon handle substrate 82S may reside underneath the second isolation sections 56S. As such, the second interfacial layer 80S/the second buffer structure 84S and the second isolation sections 56S separate the second active layer 36S from the second silicon handle substrate 82S.

Next, the second top bonding layer 16B is formed over the second BEOL portion 34S of the second device region 22S, as illustrated in FIG. 5B. The second top bonding layer 16B is formed of a same material as the first bottom bonding layer 16A, such as silicon oxide. The second top bonding layer 16B is engineered to have a proper thickness for subsequent planarization and bonding steps.

A second top via cavity 94 is then formed through the second top bonding layer 16B, and extends into the second BEOL portion 34S of the second device region 22S to expose a top surface portion of one of the second connecting layer 60S-2, as illustrated in FIG. 5C. The second top via cavity 94 does not extend toward or into the portions of the second device region 22S where the switch FET (the second active layer 36S) provided in the second FEOL portion 32S is located. The second top via cavity 94 may have a shape of a cuboid, a polygon, a cylinder, or a cone and has a depth greater than a thickness of the second top bonding layer 16B. The second top via cavity 94 may be formed by a photo masking process and an etching process. The etching process is designed to be selective to metals, which means the etching process removes portions of the second top bonding layer 16B (and maybe portions of second dielectric layers 62S) until the second connecting layer 60S-2 is reached.

The second top via 30B is formed in the second top via cavity 94 to complete a bonding-ready wafer slice 96 including the second device region 22S, as illustrated in FIG. 5D. The second top via 30B may be formed by filling the second top via cavity 94 with one or more appropriate materials. The appropriate material is required to be electrically conductive, such as platinum, gold, silver, copper, aluminum, tungsten, titanium, electrically conductive epoxy, or other suitable materials.

For defect-free and void-free wafer slice bonding, a topside of the bonding-ready wafer slice 96 needs to be planarized with a nano-meter range flatness, as illustrated in FIG. 5E. The CMP technology may be utilized in the planarization process. Since the topside of the bonding-ready wafer slice 96 contains regions of both silicon oxide (the second top bonding layer 16B) and electrically conductive material (the second top via 30B), a combination of different CMP slurries and wheels may be necessary. If the second top via 30B is formed of copper and will be bonded to the first through-via 30A using hybrid copper-copper bonding, it is desirable that the second top via 30B be recessed by an appropriate amount compared to the second top bonding layer 16B. Such recess 98 (from a planarized top surface of the second top bonding layer 16B to a planarized top surface of the second top via 30B) has a depth between 0.2 nm and 200 nm. This can be accomplished with a proper choice of copper/oxide slurries.

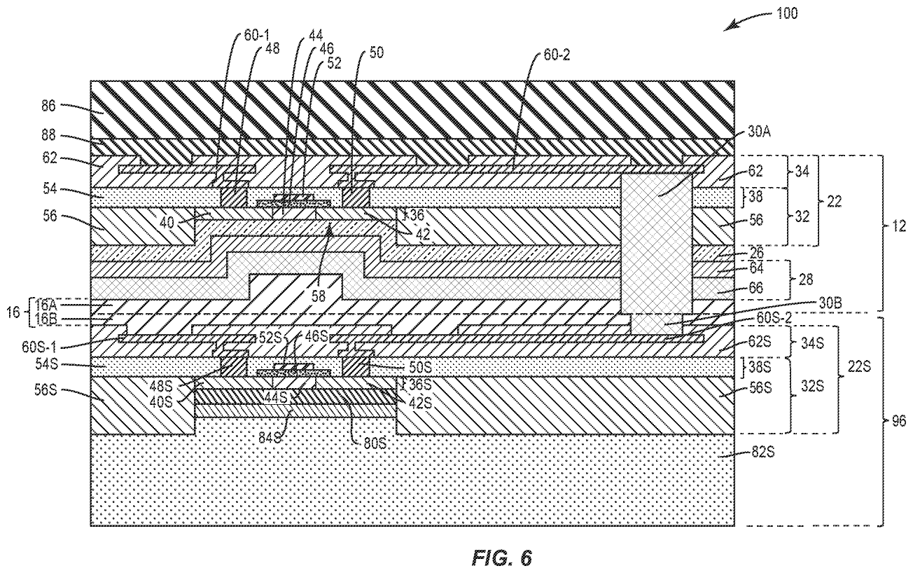

A bonding step is then followed to form a precursor package 100, as illustrated in FIG. 6. The first wafer slice 12 is placed over the bonding-ready wafer slice 96, such that the bottom surface of the first bottom bonding layer 16A directly faces the top surface of the second top bonding layer 16B. Suitable wafer alignment tools may be used to align the first wafer slice 12 with the bonding-ready wafer slice 96, such that the first through-via 30A in the first wafer slice 12 is vertically aligned with the second top via 30B in the bonding-ready wafer slice 96.

A number of different methods may be utilized to implement the bonding step, and one of them is called a direct bonding (DB) process. In the DB process, first bonding is achieved between the first bottom bonding layer 16A and the second top bonding layer 16B at a room temperature. Since the bottom surface of the first bottom bonding layer 16A of the first wafer slice 12 and the top surface of the second top bonding layer 16B of the bonding-ready wafer slice 96 are properly planarized (flat enough in nano meter range), when the first wafer slice 12 and the bonding-ready wafer slice 96 are brought together, an intimate connection will exist between the first bottom bonding layer 16A and the second top bonding layer 16B. Then, a second bonding between the first through-via 30A in the first wafer slice 12 and the second top via 30B in the bonding-ready wafer slice 96 could be achieved by careful heating cycles. If the first through-via 30A and the second top via 30B are formed of copper, the heating cycles compress the copper-copper metal joints and create a high-quality copper-copper low resistance bond. The first through-via 30A and the second top via 30B are bonded directly together to form the first via structure 30. As such, the second switch FET provided in the second device region 22S could be electrically connected to the first switch FET provided in the first device region 22 through the second connecting layer 60S-2, the first via structure 30, and the first connecting layer 60-2.

Notice that, between the first device region 22 in the first wafer slice 12 and the second device region 22S in the bonding-ready wafer slice 96 (becoming the second wafer slice 12S in the following steps), there are the first bonding region 16 (the first bottom bonding layer 16A and the second top bonding layer 16B), optionally the first enhancement region 28 (the first barrier layer 64 and/or the first thermally conductive layer 66), optionally the first passivation layer 26, and the first via structure 30 (the first through-via 30A and the second top via 30B). In a desired case, silicon crystal (which has no germanium, nitrogen, or oxygen content) does not exist between the first device region 22 and the second device region 22S. Each of the first barrier layer 64, the first thermally conductive layer 66, and the first bonding region 16 includes silicon composite, but no silicon crystal.

The second silicon handle substrate 82S is then selectively removed to provide a first etched package 102, as illustrated in FIG. 7. Since the second silicon handle substrate 82S and the second buffer structure 84S/the second interfacial layer 80S have different germanium concentrations, they may have different reactions to a same etching technique (for instance: different etching speeds with a same etchant). Typically, the higher the germanium concentration, the better the etching selectivity between the second silicon handle substrate 82S and the second buffer structure 84S (or between the second silicon handle substrate 82S and the second interfacial layer 80S). Consequently, the etching system may be capable of identifying the presence of the second buffer structure 84S/the second interfacial layer 80S (presence of germanium), and capable of indicating when to stop the etching process. As such, the selective removal stops at the second buffer structure 84S or the second interfacial layer 80S.

Since the second isolation sections 56S extend vertically beyond the second buffer structure 84S, the removal of the second silicon handle substrate 82S will provide the second opening 58S underneath the second active layer 36S and within the second isolation sections 56S. Removing the second silicon handle substrate 82S may be provided by a mechanical grinding process and an etching process or provided by the etching system itself. As an example, the second silicon handle substrate 82S may be ground to a thinner thickness to reduce the following etching time. An etching process is then performed to at least completely remove the remaining second silicon handle substrate 82S. The etching process may be provided by a wet etching system with an etchant chemistry, which is at least one of TMAH, KOH, NaOH, ACH, and XeF2, or a dry etching system, such as a reactive ion etching system with a chlorine-based gas chemistry. During the removal process, the second isolation sections 56S are not removed and protect sides of the second active layer 36S.

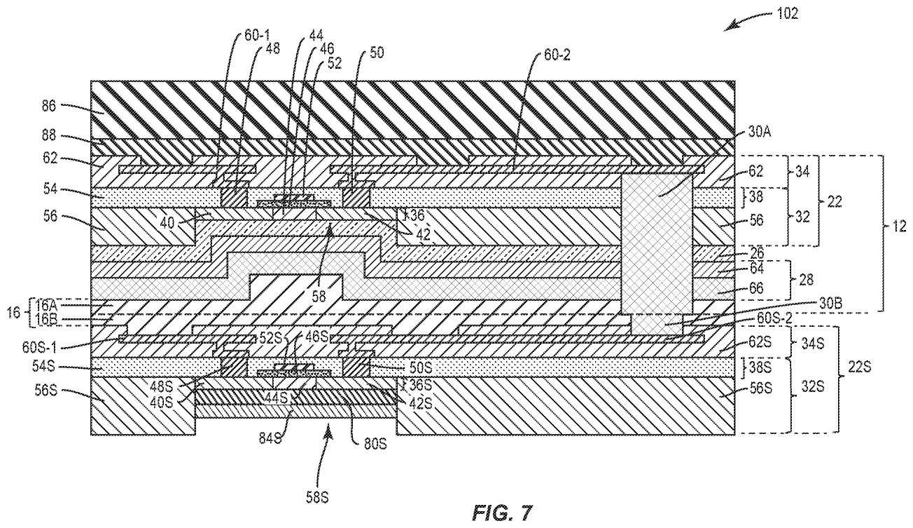

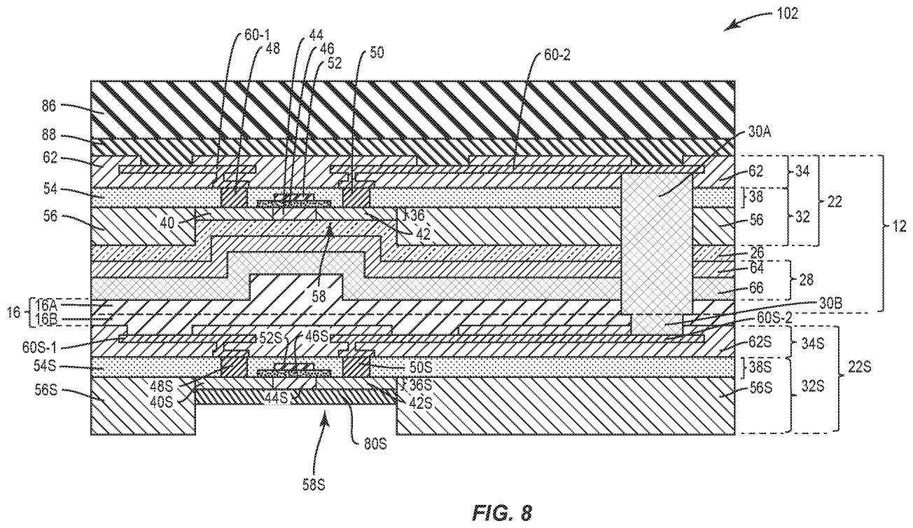

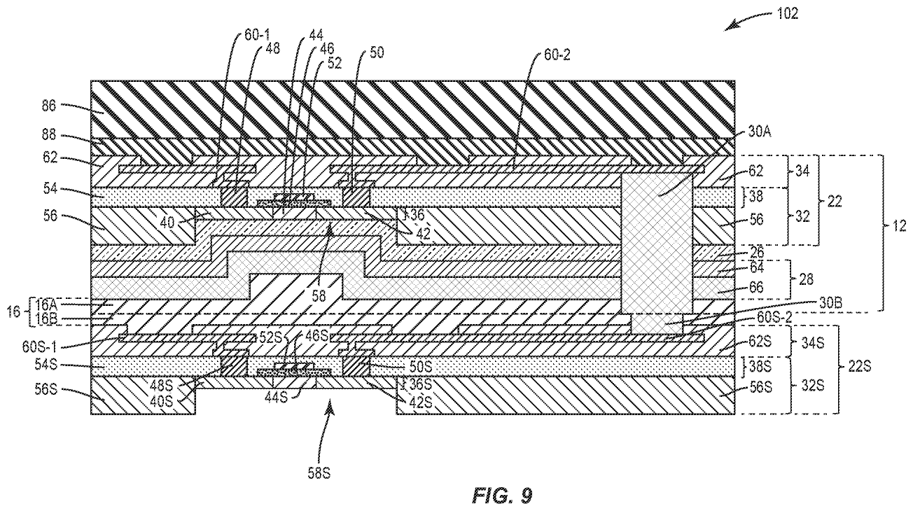

Due to the narrow gap nature of the SiGe material, it is possible that the second buffer structure 84S and/or the second interfacial layers 80S may be conductive (for some type of devices). The second buffer structure 84S and/or the second interfacial layers 80S may cause appreciable leakage between the second source 40S and the second drain 42S of the second active layer 36S. Therefore, in some applications, such as FET switch applications, it is desirable to also remove the second buffer structure 84S and the second interfacial layers 80S, as illustrated in FIGS. 8 and 9. The second active layer 36S is exposed in the second opening 58S. The second buffer structure 84S and the second interfacial layer 80S may be removed by the same etching process used to remove the second silicon handle substrate 82S, or may be removed by another etching process, such as a chlorine-base dry etching system (Chlorine or fluorine-based) and/or a wet etching (using TMAH, NH4OH:H2O2, H2O2, etc.). Herein, if the second interfacial layer 80S is thin enough, it may not cause any appreciable leakage between the second source 40S and the second drain 42S of the second FEOL portion 32S. In that case, the second interfacial layer 80S may be left (not shown).

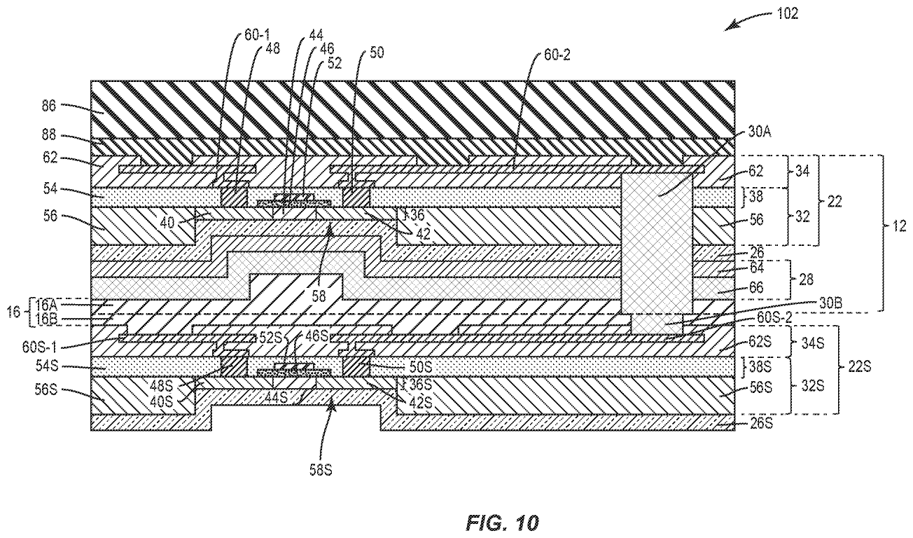

In some applications, after the removal of the second silicon handle substrate 82S, the second buffer structure 84S, and the second interfacial layer 80S, the second active layer 36S may be passivated to achieve further low levels of current leakage in the device. The second passivation layer 26S may be formed directly underneath the second FEOL portion 32S of the second device region 22S, as illustrated in FIG. 10. Herein, the second passivation layer 26S may extend over the entire bottom surface of the second FEOL portion 32S, such that the second passivation layer 26S continuously covers exposed surfaces within the second opening 58S and the bottom surfaces of the second isolation sections 56S. In some applications, the second passivation layer 26S may only cover the bottom surface of the second active layer 36S and resides within the second opening 58S without covering the bottom surfaces of the second isolation sections 56S (not shown). The second passivation layer 26S may be formed of silicon oxide by a plasma enhanced deposition process, an anodic oxidation process, an ozone-based oxidation process, and a number of other proper techniques.

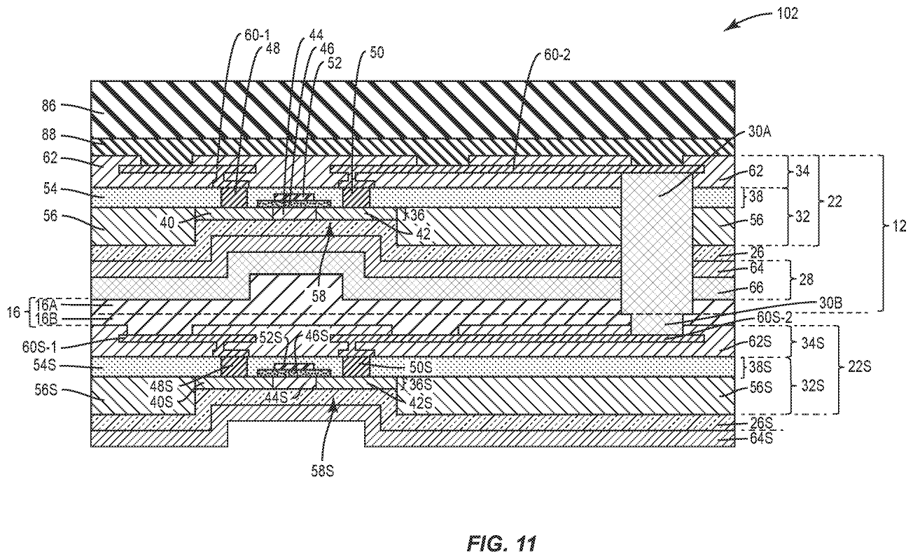

Next, the second barrier layer 64S is applied directly underneath the second passivation layer 26S, as illustrated in FIG. 11. The second barrier layer 64S is configured to provide a superior barrier to moisture and impurities, which could diffuse into the second channel 44S of the second active layer 36S and cause reliability concerns in the device. In addition, the second barrier layer 64S may also be engineered so as to provide additional tensile strain to the second device region 22S. Such strain may be beneficial in providing additional improvement of electron mobility in n-channel devices. If the second passivation layer 26S is formed only with the second opening 58S, the second barrier layer 64S continuously covers exposed surfaces within the second opening 58S (at the bottom surface of the second passivation layer 26S and side surface portions of the second isolation sections 56S) and bottom surfaces of the second isolation sections 56S (not shown). In some applications, the second barrier layer 64S, which is formed of silicon nitride with a thickness between 2000 Å and 10 μm, may further passivate the second active layer 36S. In such case, there may be no need for the second passivation layer 26S. The second barrier layer 64S always extends over the bottom surface of the second active layer 36S. The second barrier layer 64S may be formed by a chemical vapor deposition system such as a PECVD system, or an ALD system, such as a PEALD system.

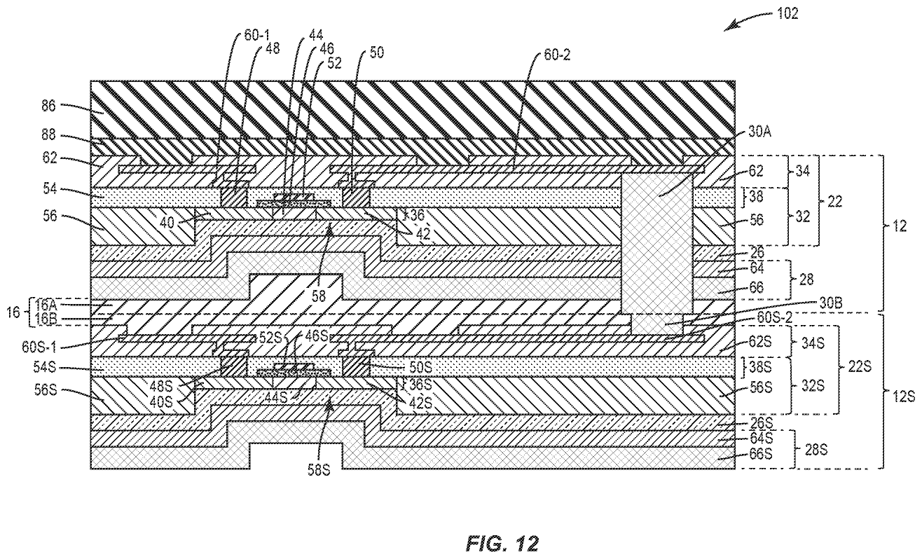

The second thermally conductive layer 66S is then applied underneath the second barrier layer 64S to form the second enhancement region 28S, and the second wafer slice 12S is completed, as illustrated in FIG. 12. The second thermally conductive layer 66S, which may be formed of aluminum nitride with a thickness between 0.1 μm and 20 μm, is configured to provide superior thermal dissipation for the second device region 22S, in the order of 275 W/mk while retaining superior electrically insulating characteristics. The second thermally conductive layer 66S might be very important to the overall thermal behavior of the stacked wafer slices. If power dissipation is not of a concern, then the second thermally conductive layer 66S may be omitted. The second thermally conductive layer 66S may be formed by CVD, ALD, or other similar methods known to those skilled in the art of semiconductor processing.

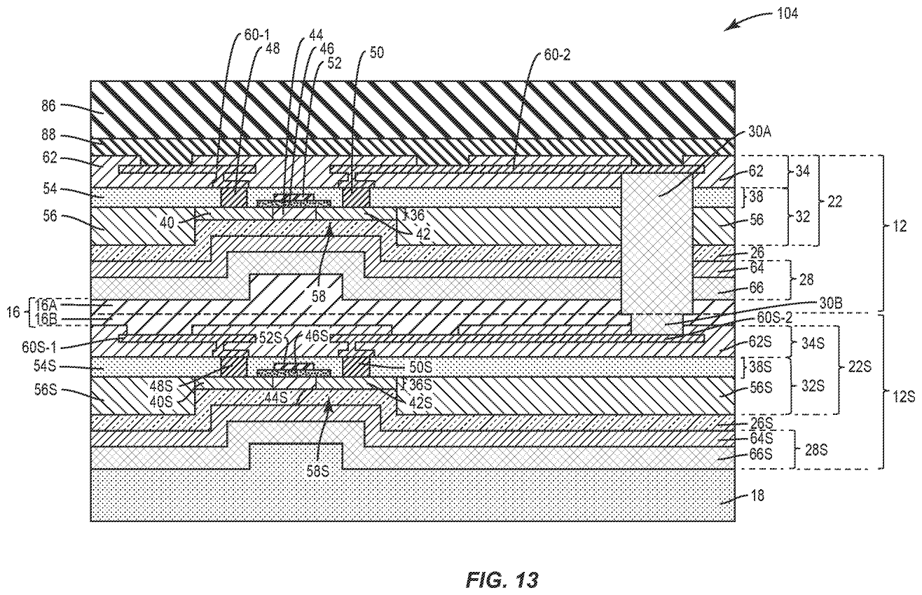

After the second enhancement region 28S is formed, the mold compound 18 is applied underneath the second enhancement region 28S to provide a molded package 104, as illustrated in FIG. 13. Herein, the mold compound 18 fills remaining portions of the second opening 58S and fully covers the second enhancement region 28S. The mold compound 18 may be applied by various procedures, such as compression molding, sheet molding, overmolding, transfer molding, dam fill encapsulation, and screen print encapsulation. The mold compound 18 may have a superior thermal conductivity between 1 W/m·K and 100 W/m·K, or between 7 W/m·K and 20 W/m·K. The mold compound 18 may have a dielectric constant less than 8, or between 3 and 5. During the molding process of the mold compound 18, the temporary carrier 86 provides mechanical strength and rigidity to the package. A curing process (not shown) is then performed to harden the mold compound 18. The curing temperature is between 100° C. and 320° C. depending on which material is used as the mold compound 18. After the curing process, the mold compound 18 may be thinned and/or planarized (not shown).

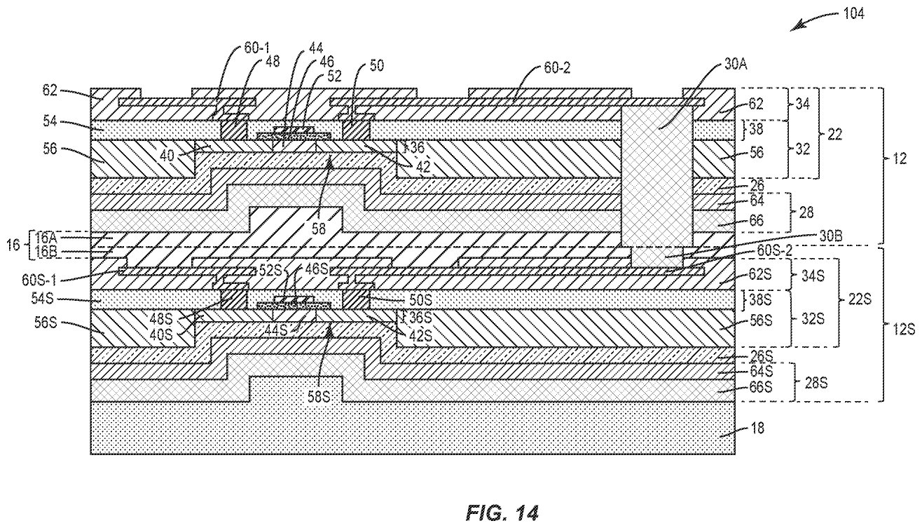

The temporary carrier 86 is then detached from the molded package 104, and the attaching layer 88 is cleaned from the molded package 104, as illustrated in FIG. 14. A number of detaching processes and cleaning processes may be applied depending on the nature of the temporary carrier 86 and the attaching layer 88 chosen in the earlier steps. For instance, the temporary carrier 86 may be mechanically detached using a lateral blade process with the stack heated to a proper temperature. Other suitable processes involve radiation of UV light through the temporary carrier 86 if it is formed of a transparent material, or chemical detaching using a proper solvent. The attaching layer 88 may be eliminated by wet or dry etching processes, such as proprietary solvents and plasma washing. After the detaching and cleaning process, top portions of the first device region 22 are exposed. In one embodiment, several top surface portions of the first connecting layers 60-1 and 60-2 are exposed through the first dielectric layers 62, which may function as input/output (I/O) ports of the molded package 104. As such, the molded package 104 may be electrically verified to be working properly at this point.

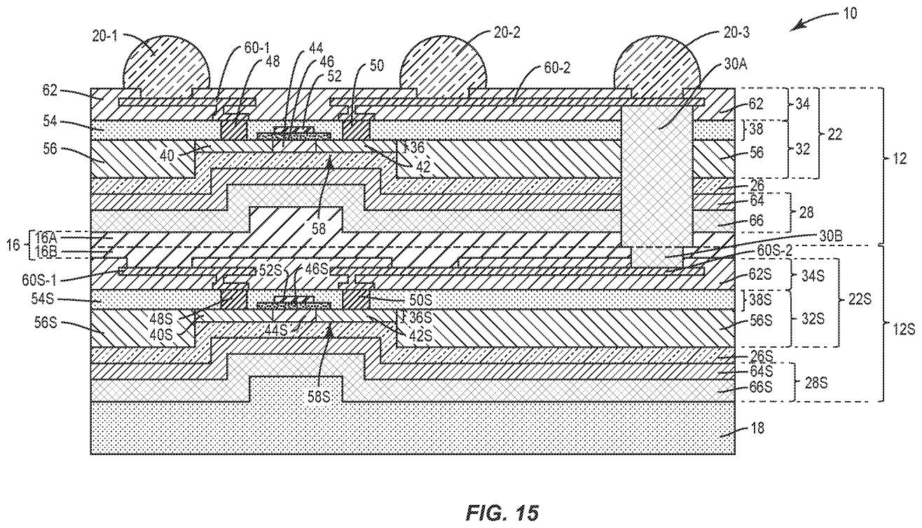

At last, a number of the bump structures 20 are formed to provide the microelectronics package 10, as illustrated in FIG. 15. Each bump structure 20 is formed at the top of the microelectronics package 10 and electrically coupled to an exposed top portion of the corresponding first connecting layer 60 through the first dielectric layers 62. For the purpose of this illustration, the first bump structure 20-1 is connected to the first source contact 48 through one of the first connecting layer 60-1, while the second bump structure 20-2 and the third bump structure 20-3 are connected to the first drain contact 50 through another one of the first connecting layer 60-2. In addition, the second bump structure 20-2 and the third bump structure 20-3 are connected to the second FET provided in the second device region 22S through the first connecting layer 60-2, the first via structure 30, and the second connecting layer 60S-2. In addition, each bump structure 20 protrudes vertically from the first dielectric layers 62.

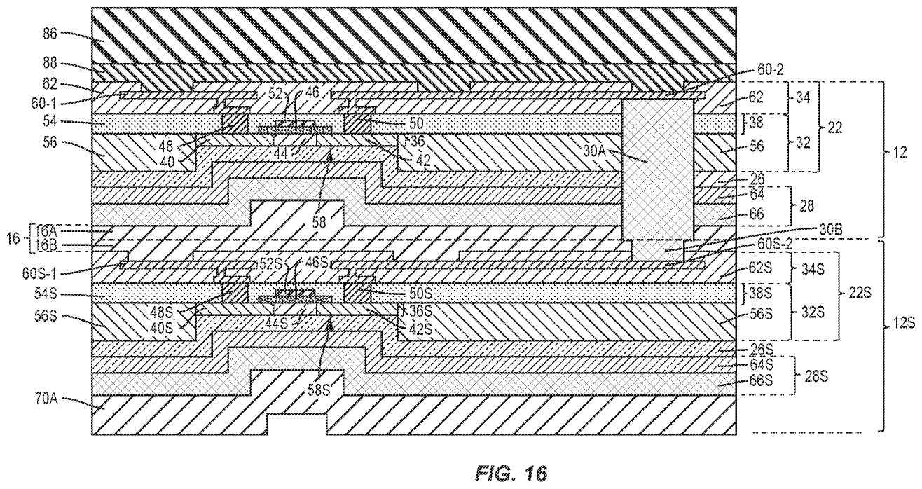

In another embodiment, FIGS. 16-30 provide an alternative process that illustrates extra steps to fabricate the second microelectronics package 68, which includes three vertically stacked wafer slices as illustrated in FIG. 2. Although the exemplary steps are illustrated in a series, the exemplary steps are not necessarily order dependent. Some steps may be done in a different order than that presented. Further, processes within the scope of this disclosure may include fewer or more steps than those illustrated in FIGS. 16-30.

After the second enhancement region 28S is formed as shown in FIG. 12, the second bottom bonding layer 70A is formed underneath the second enhancement region 28S, as illustrated in FIG. 16. The second bottom bonding layer 70A is configured to be used at a later part of the process to connect to an extra wafer slice. The second bottom bonding layer 70A may be formed of silicon oxide, and is engineered to have a proper thickness for subsequent planarization and bonding steps. If the entire second enhancement region 28S is omitted, there might not be a need for the second bottom bonding layer 70A, since the second passivation layer 26S (formed of silicon oxide) may also be used for bonding to the extra wafer slice.

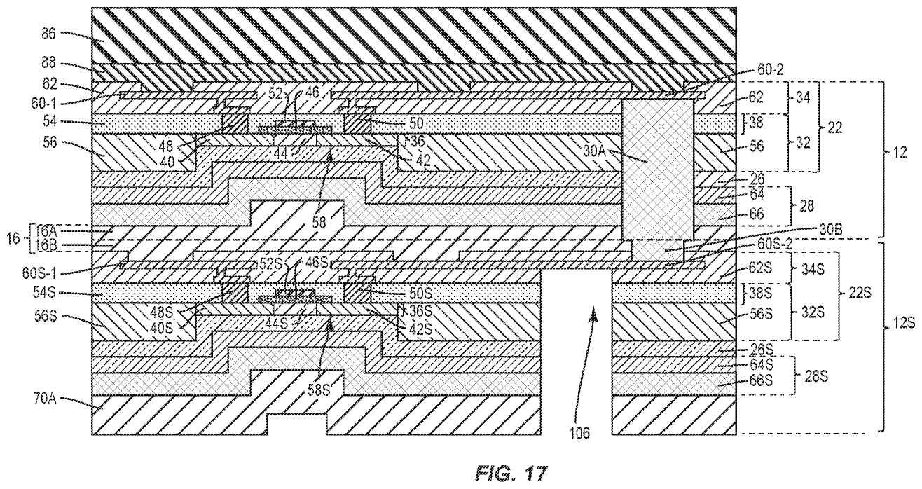

Next, a second through-via cavity 106 is formed through the second bottom bonding layer 70A, the second enhancement region 28S, and the second passivation layer 26S, and extends into the second device region 22S to expose a bottom surface portion of one of the second connecting layer 60S-2, as illustrated in FIG. 17. The second through-via cavity 106 does not extend through or into the portions of the second device region 22S where the second active layer 36S are located. The second through-via cavity 106 may have a shape of a cuboid, a polygon, a cylinder, or a cone and has a depth greater than a thickness combination of the second bottom bonding layer 70A, the second enhancement region 28S, and the second passivation layer 26S. The second through-via cavity 106 may be formed by a photo masking process and an etching process. The etching process is designed to be selective to metals, which means the etching process proceeds (removing portions of the second bottom bonding layer 70A, portions of the second enhancement region 28S, and portions of the second passivation layer 26S) until the second connecting layer is reached.

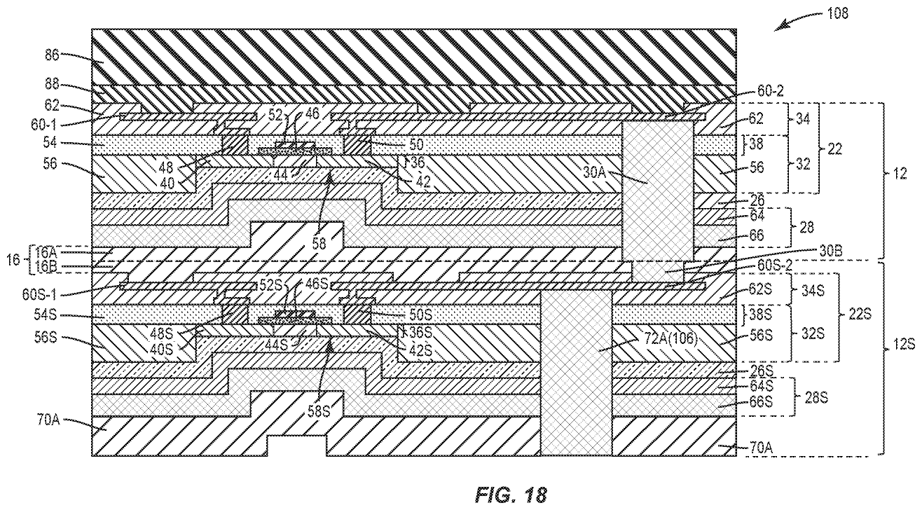

The second through-via 72A is then formed in the second through-via cavity 106 to form a bonding-ready wafer combo 108 with the completed first wafer slice 12 and the second wafer slice 12S, as illustrated in FIG. 18. The second through-via 72A may be formed by filling the second through-via cavity 106 with one or more appropriate materials. The appropriate material is required to be electrically conductive, such as platinum, gold, silver, copper, aluminum, tungsten, titanium, electrically conductive epoxy, or other suitable materials.

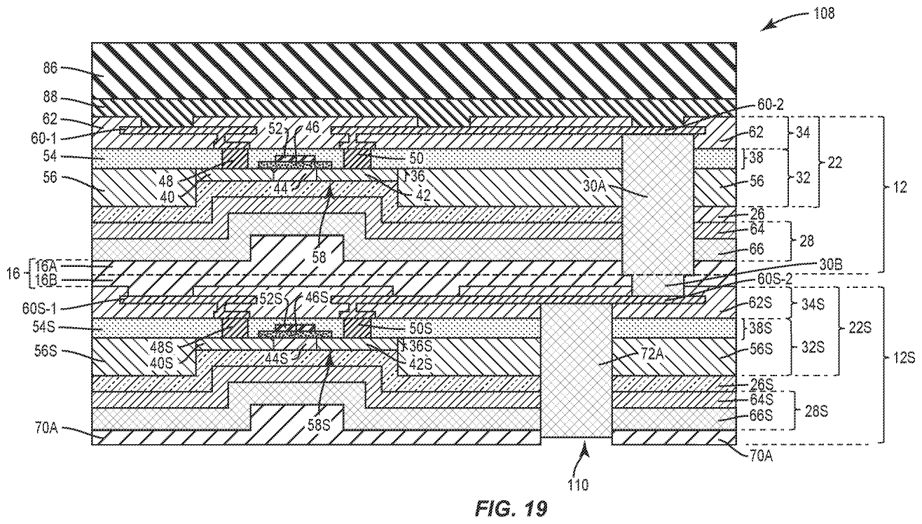

For defect-free and void-free wafer slice bonding, a backside of the second wafer slice 12s (backside of the bonding-ready wafer combo 108) needs to be planarized with a nano-meter range flatness. CMP technology may be utilized in the planarization process. Since the backside of the second wafer slice 12s contains regions of both silicon oxide (the second bottom bonding layer 70A) and electrically conductive material (the second through-via 72A), a combination of different CMP slurries and wheels may be necessary. If the second through-via 72A is formed of copper and will be bonded to another copper via using hybrid copper-copper bonding, it is desirable that the second through-via 72A be recessed by an appropriate amount compared to the second bottom bonding layer 70A, as illustrated in FIG. 19. Such recess 110 (from a planarized bottom surface of the second bottom bonding layer 70A to a planarized bottom surface of the second through-via 72A) has a depth between 0.2 nm and 200 nm. This can be accomplished with a proper choice of copper/oxide slurries.

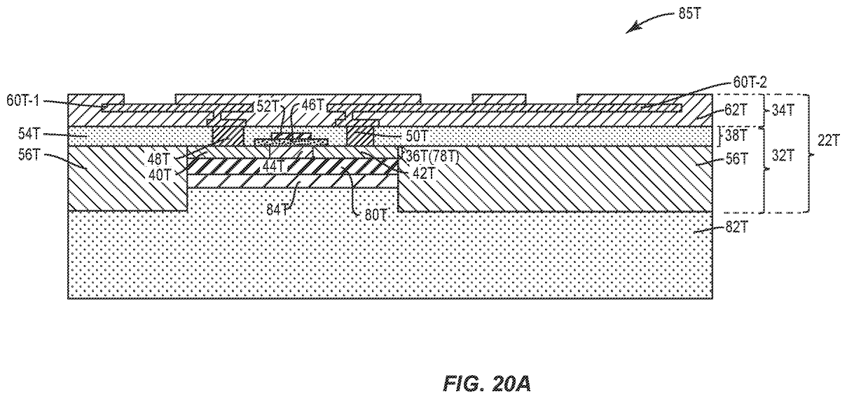

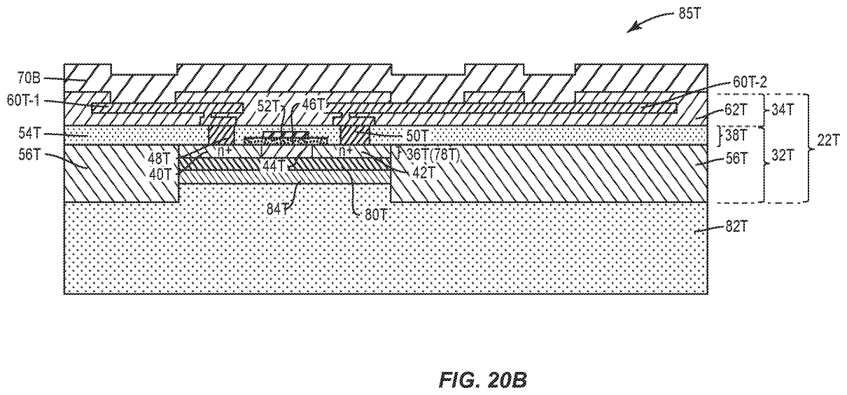

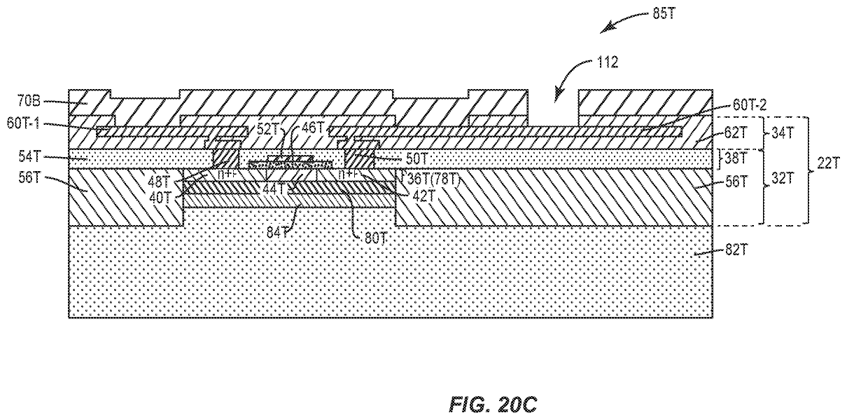

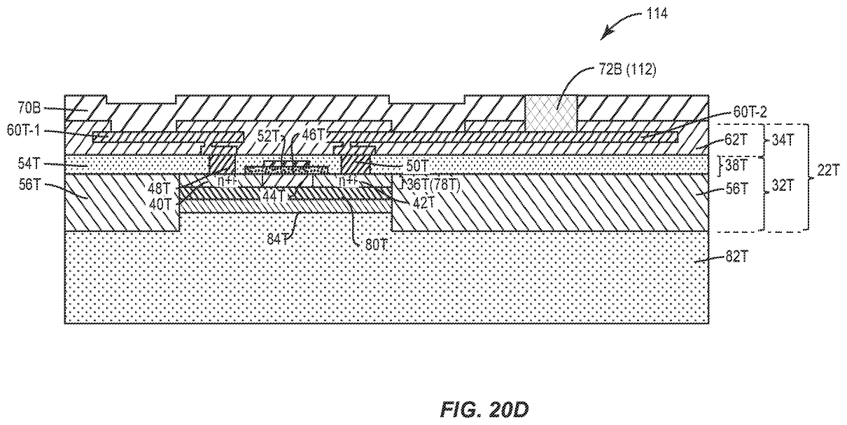

With reference to FIGS. 20A through 20E, an extra bonding-ready wafer slice, which includes the third device region 22T, is prepared for the second microelectronics package 68. Similar as the first/second precursor wafer slice 85/85S, a third precursor wafer slice 85T is provided as illustrated in FIG. 20A. The third precursor wafer slice 85T includes the third device region 22T with the third FEOL portion 32T and the third BEOL portion 34T, a third interfacial layer 80T, a third buffer structure 84T, and a third silicon handle substrate 82T.

The third BEOL portion 34T is formed over the third FEOL portion 32T and includes the third connecting layers 60T formed within the third dielectric layers 62T. The third connecting layers 60T may have one or more top portions not covered by the third dielectric layers 62T, such that the third connecting layers 60T may be electrically connected to external components not within the third precursor wafer slice 85T.

The third FEOL portion 32T, which may be configured to provide the third switch FET, includes the third active layer 36T and the third contact layer 38T. The third active layer 36T is formed from a third silicon epitaxial layer 78T, and may include the third source 40T, the third drain 42T, and the third channel 44T between the third source 40T and the third drain 42T. The third contact layer 38T, which is formed underneath the third BEOL portion 34T and over the third active layer 36T, is configured to connect the third active layer 36T to the third BEOL portion 34T. The third contact layer 38T includes the third gate structure 46T, the third source contact 48T, the third drain contact 50T, and the third gate contact 52T. The third gate structure 46T may be formed of silicon oxide, and extends horizontally over the third channel 44T (i.e., from over the third source 40T to over the third drain 42T). The third source contact 48T is connected to and over the third source 40T, the third drain contact 50T is connected to and over the third drain 42T, and the third gate contact 52T is connected to and over the third gate structure 46T. The third insulating material 54T may be formed around the third source contact 48T, the third drain contact 50T, the third gate structure 46T, and the third gate contact 52T to electrically separate the third source 40T, the third drain 42T, and the third gate structure 46T. For the purpose of this illustration, one of the third connecting layers 60T-1 in the third BEOL portion 34T is connected to the third source contact 48T and another one of the third connecting layers 60T-2 of the third BEOL portion 34T is connected to the third drain contact 50T. In different applications, the third FEOL portion 32T may have different FET configurations or provide different device components.

In addition, the third FEOL portion 32T also includes the third isolation sections 56T, which reside underneath the third insulating material 54T of the third contact layer 38T. The third isolation sections 56T extend from the bottom surface of the third contact layer 38T, through the third silicon epitaxial layer 78T, the third interfacial layer 80T, and the third buffer structure 84T, and extend into the third silicon handle substrate 82T. Herein, the third active layer 36T is fabricated from the third silicon epitaxial layer 78T, and the third silicon epitaxial layer 78T, the third interfacial layer 80T, the third buffer structure 84T, and the third silicon handle substrate 82T are provided by a starting wafer slice, which has a similar/same configuration and materials as the first starting wafer slice 76. As such, the third isolation sections 56T surround the third active layer 36T, the remaining third interfacial layer 80T, and the remaining third buffer structure 84T. The third isolation sections 56T are configured to electrically separate the third active layer 36T from other devices formed in the same third precursor wafer slice 85T (not shown). The third isolation sections 56T may be formed by STI. The third isolation sections 56T may be formed of silicon dioxide, which may be resistant to etching chemistries such as TMAH, XeF₂, KOH, NaOH, or ACH, and may be resistant to a dry etching system, such as a RIE system with a chlorine-based gas chemistry.

The third interfacial layer 80T may be directly underneath the third active layer 36T, and the third buffer structure 84T remains underneath the third interfacial layer 80T. The third silicon handle substrate 82T remains underneath the third buffer structure 84T, and portions of the third silicon handle substrate 82T may reside underneath the third isolation sections 56T. As such, the third interfacial layer 80T/the third buffer structure 84T and the third isolation sections 56T separate the third active layer 36T from the third silicon handle substrate 82T.

Next, the third top bonding layer 70B is formed over the third BEOL portion 34T of the third device region 22T, as illustrated in FIG. 20B. The third top bonding layer 70B is formed of a same material as the second bottom bonding layer 70A, such as silicon oxide. The third top bonding layer 70B is engineered to have a proper thickness for subsequent planarization and bonding steps.

A third top via cavity 112 is then formed through the third top bonding layer 70B, and extends into the third BEOL portion 34T of the third device region 22T to expose a top surface portion of one of the third connecting layer 60T-2, as illustrated in FIG. 20C. The third top via cavity 112 does not extend toward or into the portions of the third device region 22T where the switch FET (the third active layer 36T) provided in the third FEOL portion 32T is located. The third top via cavity 112 may have a shape of a cuboid, a polygon, a cylinder, or a cone and has a depth greater than a thickness of the third top bonding layer 70B. The third top via cavity 112 may be formed by a photo masking process and an etching process. The etching process is designed to be selective to metals, which means the etching process removes portions of the third top bonding layer (and maybe portions of third dielectric layers 62T) until the third connecting layer 60T-2 is reached.

The third top via 72B is formed in the third top via cavity 112 to complete the extra bonding-ready wafer slice 114 including the third device region 22T, as illustrated in FIG. 20D. The third top via 72B may be formed by filling the third top via cavity 112 with one or more appropriate materials. The appropriate material is required to be electrically conductive, such as platinum, gold, silver, copper, aluminum, tungsten, titanium, electrically conductive epoxy, or other suitable materials.

For defect-free and void-free wafer slice bonding, a topside of the extra bonding-ready wafer slice 114 needs to be planarized with a nano-meter range flatness, as illustrated in FIG. 20E. The CMP technology may be utilized in the planarization process. Since the topside of the extra bonding-ready wafer slice 114 contains regions of both silicon oxide (the third top bonding layer 70B) and electrically conductive material (the third top via 72B), a combination of different CMP slurries and wheels may be necessary. If the third top via 72B is formed of copper and will be bonded to the second through-via 72A using hybrid copper-copper bonding, it is desirable that the third top via 72B be recessed by an appropriate amount compared to the third top bonding layer 70B. Such recess 116 (from a planarized top surface of the third top bonding layer 70B to a planarized top surface of the third top via 72B) has a depth between 0.2 nm and 200 nm. This can be accomplished with a proper choice of copper/oxide slurries.

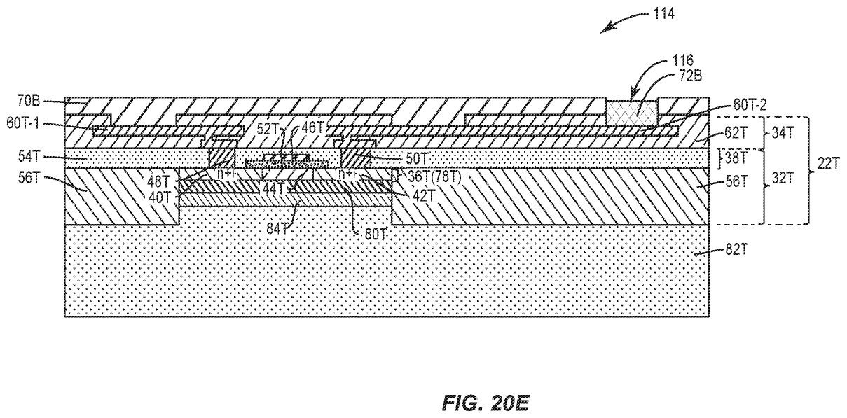

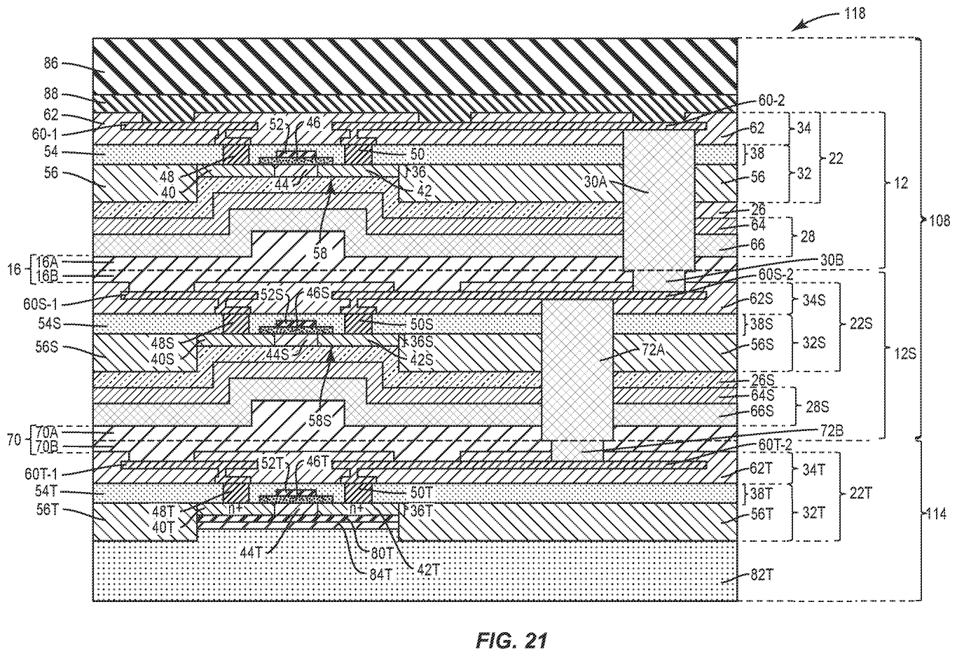

A bonding step is then followed to form a second precursor package 118, as illustrated in FIG. 21. The bonding-ready wafer combo 108 (including the first wafer slice 12 and the second wafer slice 12S) is placed over the extra bonding-ready wafer slice 114, such that the bottom surface of the second bottom bonding layer 70A directly faces the top surface of the third top bonding layer 70B. Suitable wafer alignment tools may be used to align the bonding-ready wafer combo 108 with the extra bonding-ready wafer slice 114, such that the second through-via 72A in the bonding-ready wafer combo 108 (in the second wafer slice 12S) is vertically aligned with the third top via 72B in the extra bonding-ready wafer slice 114.

A number of different methods may be utilized to implement this bonding step, and one of them is called a DB process. In the DB process, first bonding is achieved between the second bottom bonding layer 70A and the third top bonding layer 70B at a room temperature. Since the bottom surface of the second bottom bonding layer 70A of the second wafer slice 12S and the top surface of the third top bonding layer 70B of the extra bonding-ready wafer slice 114 are properly planarized (flat enough in nano meter range), when the second wafer slice 12S and the extra bonding-ready wafer slice 114 are brought together, an intimate connection will exist between the second bottom bonding layer 70A and the third top bonding layer 70B. Then second bonding between the second through-via 72A in the second wafer slice 12S and the third top via 72B in the extra bonding-ready wafer slice 114 could be achieved by careful heating cycles. If the second through-via 72A and the third top via 72B are formed of copper, the heating cycles compress the copper-copper metal joints and create a high-quality copper-copper low resistance bond. The second through-via 72A and the third top via 72B are bonded directly together to form the second via structure 72. As such, the third switch FET provided in the third device region 22T could be electrically connected to the second switch FET provided in the second device region 22S through the third connecting layer 60T-2, the second via structure 72, and the second connecting layer 60S-2, and further electrically connected to the first switch FET provided in the first device region 22 through the second connecting layer 60S-2, the first via structure 30, and the first connecting layer 60-2.

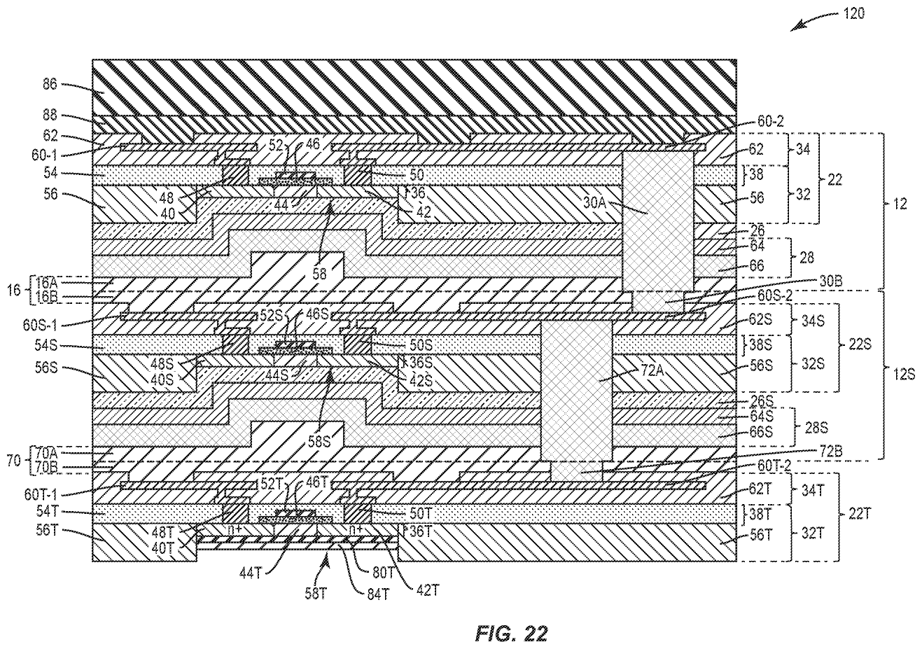

Notice that, between the second device region 22S in the second wafer slice 12S and the third device region 22T in the extra bonding-ready wafer slice 114 (becoming the third wafer slice 12T in following steps), there are the second bonding region 70 (the second bottom bonding layer 70A and the third top bonding layer 70B), optionally the second enhancement region 28S (the second barrier layer 64S and/or the second thermally conductive layer 66S), optionally the second passivation layer 26S, and the second via structure 72 (the second through-via 72A and the third top via 72B). In a desired case, silicon crystal (which has no germanium, nitrogen, or oxygen content) does not exist between the second device region 22S and the third device region 22T. Each of the second barrier layer 64S, the second thermally conductive layer 66S, and the second bonding region 70 includes silicon composite, but no silicon crystal. The third silicon handle substrate 82T is then selectively removed to provide a second etched package 120, as illustrated in FIG. 22. Since the third silicon handle substrate 82T and the third buffer structure 84T/the third interfacial layer 80T have different germanium concentrations, they may have different reactions to a same etching technique (for instance: different etching speeds with a same etchant). Typically, the higher the germanium concentration, the better the etching selectivity between the third silicon handle substrate 82T and the third buffer structure 84T (or between the third silicon handle substrate 82T and the third interfacial layer 80T). Consequently, the etching system may be capable of identifying the presence of the third buffer structure 84T/the third interfacial layer 80T (presence of germanium), and capable of indicating when to stop the etching process. As such, the selective removal stops at the third buffer structure 84T or the third interfacial layer 80T.

Since the third isolation sections 56T extend vertically beyond the third buffer structure 84T, the removal of the third silicon handle substrate 82T will provide the third opening 58T underneath the third active layer 36T and within the third isolation sections 56T. Removing the third silicon handle substrate 82T may be provided by a mechanical grinding process and an etching process or provided by the etching system itself. As an example, the third silicon handle substrate 82T may be ground to a thinner thickness to reduce the following etching time. An etching process is then performed to at least completely remove the remaining third silicon handle substrate 82T. The etching process may be provided by a wet etching system with an etchant chemistry, which is at least one of TMAH, KOH, NaOH, ACH, and XeF2, or a dry etching system, such as a reactive ion etching system with a chlorine-based gas chemistry. During the removal process, the third isolation sections 56T are not removed and protect sides of the third active layer 36T.

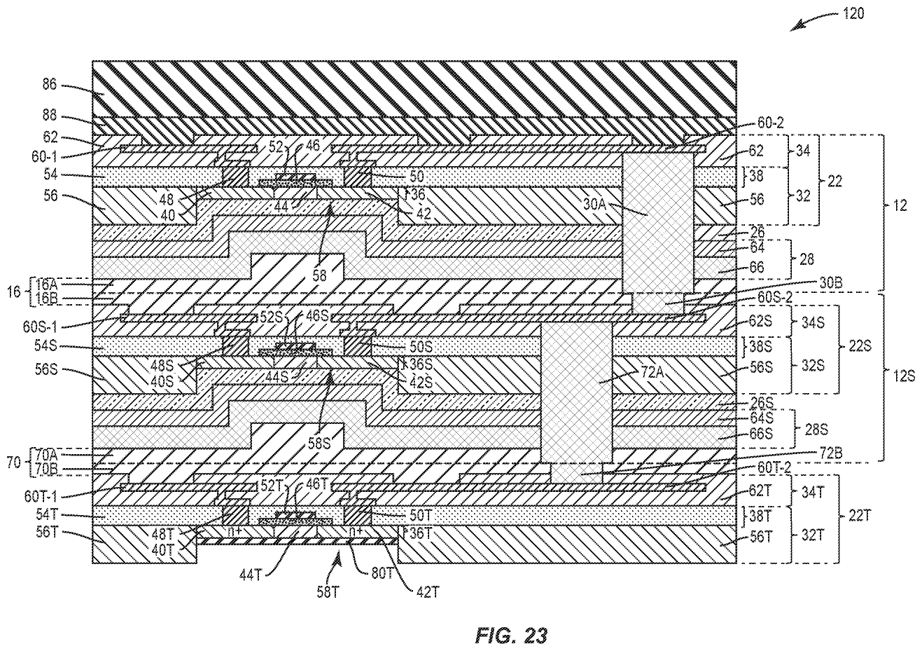

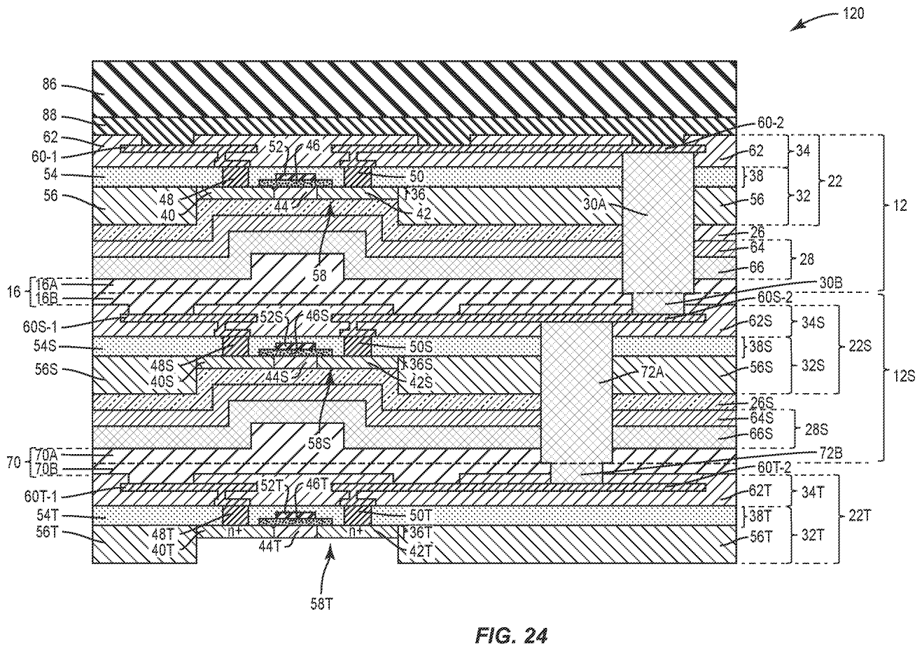

Due to the narrow gap nature of the SiGe material, it is possible that the third buffer structure 84T and/or the third interfacial layers 80T may be conductive (for some types of devices). The third buffer structure 84T and/or the third interfacial layers 80T may cause appreciable leakage between the third source 40T and the third drain 42T of the third active layer 36T. Therefore, in some applications, such as FET switch applications, it is desirable to also remove the third buffer structure 84T and the third interfacial layers 80T, as illustrated in FIGS. 23 and 24. The third active layer 36T is exposed in the third opening 58T. The third buffer structure 84T and the third interfacial layer 80T may be removed by the same etching process used to remove the third silicon handle substrate 82T, or may be removed by another etching process, such as a chlorine-base dry etching system (Chlorine or fluorine-based) and/or a wet etching (using TMAH, NH4OH:H2O2, H2O2, etc.). Herein, if the third interfacial layer 80T is thin enough, it may not cause any appreciable leakage between the third source 40T and the third drain 42T of the third FEOL portion 32T. In that case, the third interfacial layer 80T may be left (not shown).

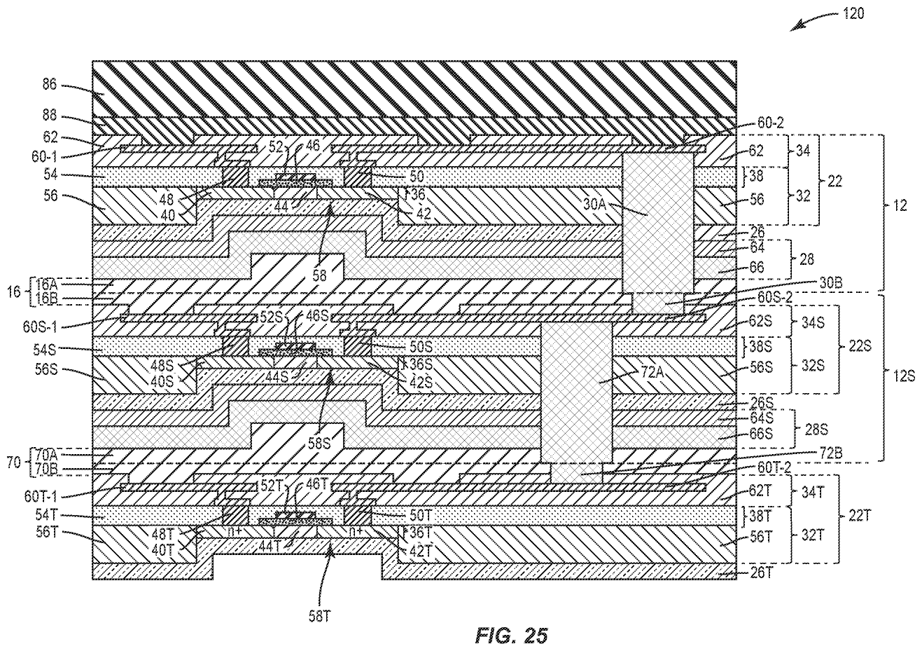

In some applications, after the removal of the third silicon handle substrate 82T, the third buffer structure 84T, and the third interfacial layer 80T, the third active layer 36T may be passivated to achieve further low levels of current leakage in the device. The third passivation layer 26T may be formed directly underneath the third FEOL portion 32T of the third device region 22T, as illustrated in FIG. 25. Herein, the third passivation layer 26T may extend over the entire bottom surface of the third FEOL portion 32T, such that the third passivation layer 26T continuously covers exposed surfaces within the third opening 58T and the bottom surfaces of the third isolation sections 56T. In some applications, the third passivation layer 26T may only cover the bottom surface of the third active layer 36T and resides within the third opening 58T without covering the bottom surfaces of the third isolation sections 56T (not shown). The third passivation layer 26T may be formed of silicon oxide by a plasma enhanced deposition process, an anodic oxidation process, an ozone-based oxidation process, and a number of other proper techniques.

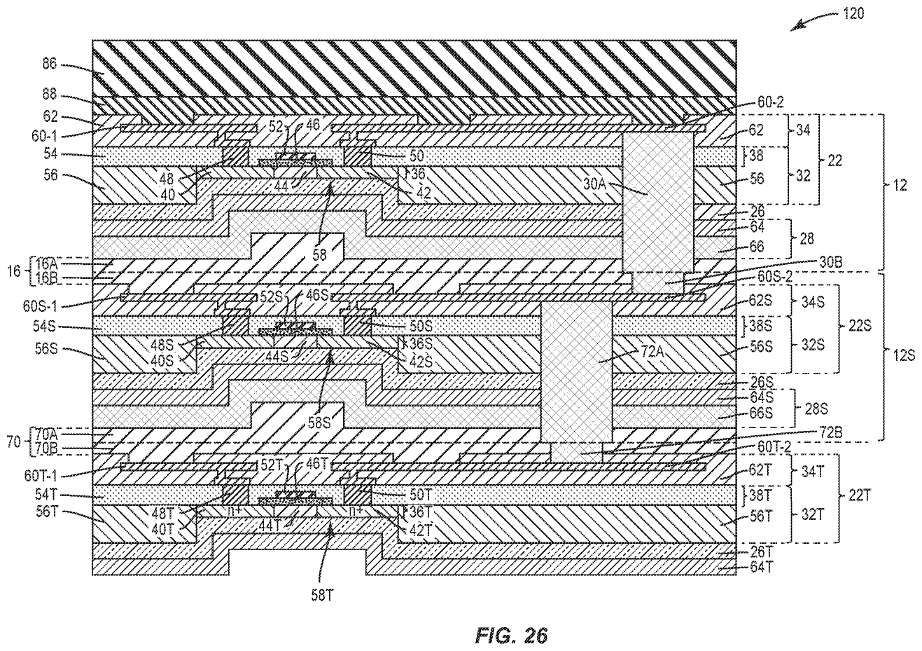

Next, the third barrier layer 64T is applied directly underneath the third passivation layer 26T, as illustrated in FIG. 26. The third barrier layer 64T is configured to provide a superior barrier to moisture and impurities, which could diffuse into the third channel 44T of the third active layer 36T and cause reliability concerns in the device. In addition, the third barrier layer 64T may also be engineered so as to provide additional tensile strain to the third device region 22T. Such strain may be beneficial in providing additional improvement of electron mobility in n-channel devices. If the third passivation layer 26T is formed only with the third opening 58T, the third barrier layer 64T continuously covers exposed surfaces within the third opening 58T (at the bottom surface of the third passivation layer 26T and side surface portions of the third isolation sections 56T) and bottom surfaces of the third isolation sections 56T (not shown). In some applications, the third barrier layer 64T, which is formed of silicon nitride with a thickness between 2000 Å and 10 μm, may further passivate the third active layer 36T. In such case, there may be no need for the third passivation layer 26T. The third barrier layer 64T always extends over the bottom surface of the third active layer 36T. The third barrier layer 64T may be formed by a chemical vapor deposition system such as a PECVD system, or an ALD system, such as a PEALD system.

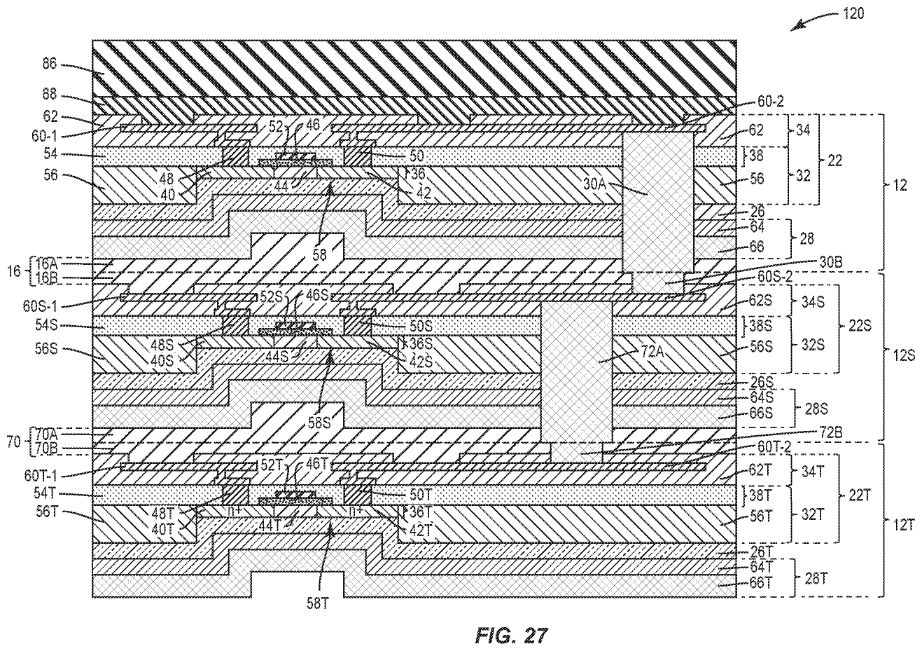

The third thermally conductive layer 66T is then applied underneath the third barrier layer 64T to form the third enhancement region 28T, and the third wafer slice 12T is completed, as illustrated in FIG. 27. The third thermally conductive layer 66T, which may be formed of aluminum nitride with a thickness between 0.1 μm and 20 μm, is configured to provide superior thermal dissipation for the third device region 22T, in the order of 275 W/mk while retaining superior electrically insulating characteristics. The third thermally conductive layer 66T might be very important to the overall thermal behavior of the stacked wafer slices. If power dissipation is not of a concern, then the third thermally conductive layer 66T may be omitted. The third thermally conductive layer 66T may be formed by CVD, ALD, or other similar methods known to those skilled in the art of semiconductor processing.

After the third enhancement region 28T is formed, the mold compound 18 is applied underneath the third enhancement region 28T to provide a molded package 122, as illustrated in FIG. 28. Herein, the mold compound 18 fills remaining portions of the third opening 58T and fully covers the third enhancement region 28T. The mold compound 18 may be applied by various procedures, such as compression molding, sheet molding, overmolding, transfer molding, dam fill encapsulation, and screen print encapsulation. The mold compound 18 may have a superior thermal conductivity between 1 W/m·K and 100 W/m·K, or between 7 W/m·K and 20 W/m·K. The mold compound 18 may have a dielectric constant less than 8, or between 3 and 5. During the molding process of the mold compound 18, the temporary carrier 86 provides mechanical strength and rigidity to the package. A curing process (not shown) is then performed to harden the mold compound 18. The curing temperature is between 100° C. and 320° C. depending on which material is used as the mold compound 18. After the curing process, the mold compound 18 may be thinned and/or planarized (not shown).

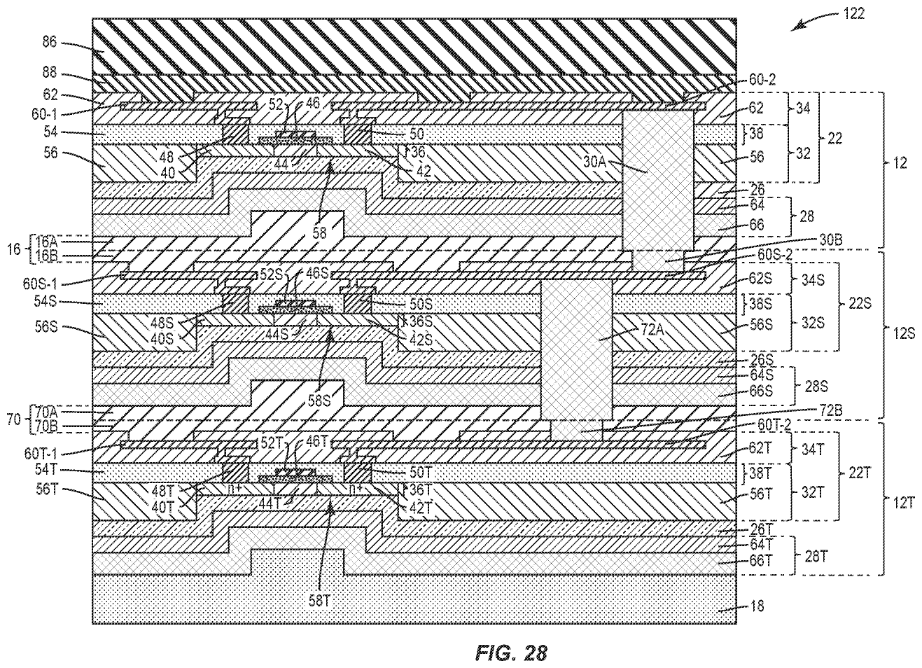

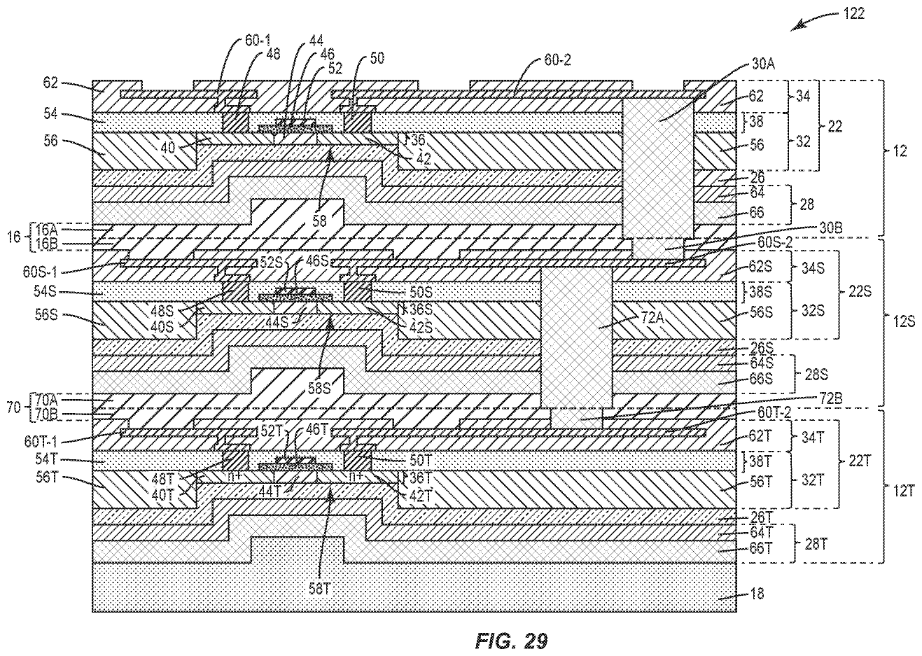

The temporary carrier 86 is then detached from the molded package 122, and the attaching layer 88 is cleaned from the molded package 122, as illustrated in FIG. 29. A number of detaching processes and cleaning processes may be applied depending on the nature of the temporary carrier 86 and the attaching layer 88 chosen in the earlier steps. For instance, the temporary carrier 86 may be mechanically detached using a lateral blade process with the stack heated to a proper temperature. Other suitable processes involve radiation of UV light through the temporary carrier 86 if it is formed of a transparent material, or chemical detaching using a proper solvent. The attaching layer 88 may be eliminated by wet or dry etching processes, such as proprietary solvents and plasma washing. After the detaching and cleaning process, top portions of the first device region 22 are exposed. In one embodiment, several top surface portions of the first connecting layers 60-1 and 60-2 are exposed through the first dielectric layers 62, which may function as input/output (I/O) ports of the molded package 122. As such, the molded package 122 may be electrically verified to be working properly at this point.

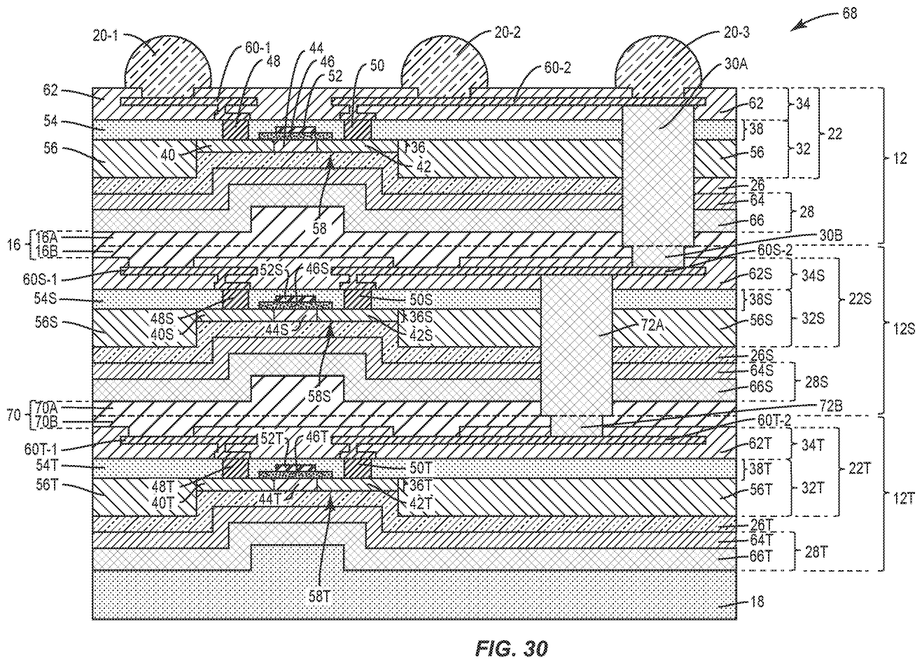

At last, a number of the bump structures 20 are formed to provide the second microelectronics package 68, as illustrated in FIG. 30. Each bump structure 20 is formed at the top of the second microelectronics package 68 and electrically coupled to an exposed top portion of the corresponding first connecting layer 60 through the first dielectric layers 62. For the purpose of this illustration, the first bump structure 20-1 is connected to the first source contact 48 through one of the first connecting layer 60-1, while the second bump structure 20-2 and the third bump structure 20-3 are connected to the first drain contact 50 through another one of the first connecting layer 60-2. In addition, the second bump structure 20-2 and the third bump structure 20-3 are connected to the second FET provided in the second device region 22S through the first connecting layer 60-2, the first via structure 30, and the second connecting layer and are further connected to the third FET provided in the third device region 22T through the second connecting layer 60S-2, the second via structure 72, and the third connecting layer 60T-2. Herein, each bump structure 20 protrudes vertically from the first dielectric layers 62.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

1. An apparatus comprising:
a first wafer slice comprising a first device region at a top of the first wafer slice, a first enhancement region, a first bottom bonding layer, and a first through-, wherein:
the first device region includes a first front-end-of-line (FEOL) portion and a first back-end-of-line (BEOL) portion that is over the first FEOL portion and includes at least one first connecting layer;
the first enhancement region is underneath the first device region and includes at least one of a first barrier layer and a first thermally conductive layer, wherein the first barrier layer is formed of silicon nitride and the first thermally conductive layer is formed of aluminum nitride;
the first bottom bonding layer, which is formed of silicon oxide, is underneath the first enhancement region and at a bottom of the first wafer slice; and
the first through-via vertically extends through the first bottom bonding layer and the first enhancement region, and extends into the first device region, wherein the at least one first connecting layer is configured to electrically connect the first FEOL portion and the first through-via; and
a second wafer slice vertically stacked underneath the first wafer slice and comprising a top bonding layer at a top of the second wafer slice and configured to bond to the first wafer slice, a second device region underneath the top bonding layer, and a top via, wherein:
the second device region includes a second FEOL portion and a second BEOL portion that is over the second FEOL portion and includes at least one second connecting layer;
the top via vertically extends through the top bonding layer and into the second BEOL portion of the second device region without extending into the second FEOL portion of the second device region; and
the top bonding layer in the second wafer slice, which is formed of silicon oxide, is directly bonded with the first bottom bonding layer, such that the top via is in contact with the first through-via, and the second FEOL portion is electrically connected to the first FEOL portion through the at least one second connecting layer, the top via, the first through-via, and the at least one first connecting layer.

2. The apparatus of claim 1 wherein between the first device region and the second device region, any layer that comprises silicon is formed only of one or more silicon composites.

3. The apparatus of claim 1 wherein:
the first BEOL portion comprises first dielectric layers, and a plurality of first connecting layers that includes the at least one first connecting layer, wherein the plurality of first connecting layers is partially covered by the first dielectric layers and is configured to electrically connect the first FEOL portion to components outside the first device region;
the first FEOL portion comprises a first contact layer underneath the first BEOL portion, a first active layer underneath the first contact layer, and first isolation sections underneath the first contact layer and surrounding the first active layer;
the second BEOL portion comprises second dielectric layers, and a plurality of second connecting layers that includes the at least one second connecting layer, wherein the plurality of second connecting layers is partially covered by the second dielectric layers and is configured to electrically connect the second FEOL portion to components outside the second device region; and
the second FEOL portion comprises a second contact layer underneath the second BEOL portion, a second active layer underneath the second contact layer, and second isolation sections underneath the second contact layer and surrounding the second active layer.

4. The apparatus of claim 3 further comprises a plurality of bump structures, which is formed over the first wafer slice, and electrically coupled to the first FEOL portion through the plurality of first connecting layers in the first BEOL portion.

5. The apparatus of claim 3 wherein the first through-via of the first wafer slice does not extend toward or into a particular portion of the first device region where the first active layer is located, and the top via of the second wafer slice does not extend toward or into a particular portion of the second device region where the second active layer is located.

6. The apparatus of claim 3 wherein the first isolation sections extend vertically beyond a bottom surface of the first active layer to define a first opening within the first isolation sections and underneath the first active layer.

7. The apparatus of claim 3 wherein a bottom surface of each first isolation section and the bottom surface of the first active layer are coplanar, such that the first FEOL portion of the first device region has a flat bottom surface.

8. The apparatus of claim 3 wherein the first wafer slice further includes a first passivation layer vertically between the first device region and the first enhancement region, wherein:
the first passivation layer continuously covers the first active layer and at least covers bottom surfaces of the first isolation sections; and
the first passivation layer is formed of silicon oxide, and the top bonding layer in the second wafer slice is formed of silicon oxide.

9. (canceled)

10. The apparatus of claim 8 wherein:
the first enhancement region includes the first barrier layer underneath the first passivation layer and the first thermally conductive layer underneath the first barrier layer and over the first bottom bonding layer;
the first barrier layer has with a thickness between 0.2 μm and 10 μm; and
the first thermally conductive layer has a thickness between 0.1 μm and 20 μm.

11. The apparatus of claim 3 wherein the second isolation sections extend vertically beyond a bottom surface of the second active layer to define a second opening within the second isolation sections and underneath the second active layer.

12. The apparatus of claim 3 wherein a bottom surface of each second isolation section and the bottom surface of the second active layer are coplanar, such that the second FEOL portion of the second device region has a flat bottom surface.

13. The apparatus of claim 3 wherein the second wafer slice further includes a second passivation layer underneath the second FEOL portion of the second device region, wherein:
the second passivation layer continuously covers the second active layer and at least covers bottom surfaces of the second isolation sections; and
the second passivation layer is formed of silicon oxide.

14. The apparatus of claim 13 wherein the second wafer slice further includes a second enhancement region underneath the second passivation layer, wherein the second enhancement region includes at least one of a second barrier layer and a second thermally conductive layer.

15. The apparatus of claim 14 wherein:
the second enhancement region includes the second barrier layer underneath the second passivation layer and the second thermally conductive layer underneath the second barrier layer;
the second barrier layer is formed of silicon nitride with a thickness between 0.2 μm and 10 μm; and
the second thermally conductive layer is formed of aluminum nitride with a thickness between 0.1 μm and 20 μm.

16. The apparatus of claim 14 further comprises a mold compound formed underneath the second enhancement region, wherein the mold compound has a thermal conductivity greater than 1 W/m·K and a dielectric constant less than 8.

17. The apparatus of claim 1 wherein the first FEOL portion provides a switch field-effect transistor (FET), and the second FEOL portion provides another switch FET.

18. The apparatus of claim 1 further comprising a third wafer slice vertically stacked underneath the second wafer slice and comprising a third top bonding layer at a top of the third wafer slice and configured to bond to the second wafer slice, a third device region underneath the third top bonding layer, and a third top via, wherein:
the second wafer slice further comprises a second passivation layer underneath the second device region, and a second through-via that vertically extends through the second passivation layer and into the second device region;
the at least one second connecting layer is configured to electrically connect the second FEOL portion and the second through-via;
the third device region includes a third FEOL portion and a third BEOL portion that is over the third FEOL portion and includes at least one third connecting layer;
the third top via vertically extends through the third top bonding layer and into the third BEOL portion of the third device region without extending into the third FEOL portion of the third device region, wherein the at least one third connecting layer is configured to electrically connect the third FEOL portion and the third top via; and
the third top via is in contact with the second through-via, such that the second FEOL portion is electrically connected to the third FEOL portion through the at least one third connecting layer, the third top via, the second through-via, and the at least one second connecting layer.

19. The apparatus of claim 18 wherein between the first device region and the second device region and between the second device region and the third device region, any layer that comprises silicon is formed only of one or more silicon composites.

20. The apparatus of claim 18 wherein:
the second passivation layer is formed of silicon oxide, and the third top bonding layer in the third wafer slice is formed of silicon oxide; and
the second passivation layer is at a bottom of the second wafer slice and directly bonded with the third top bonding layer of the third wafer slice.

21. The apparatus of claim 18 wherein:
the second wafer slice further includes a second enhancement region underneath the second passivation layer and a second bottom bonding layer underneath the second enhancement region, wherein:
the second through-via extends through the second bottom bonding layer, the second enhancement region, the second passivation layer and into the second device region;
the second enhancement region includes at least one of a second barrier layer and a second thermally conductive layer;
the second bottom bonding layer in the second wafer slice is formed of silicon oxide, and the third top bonding layer in the third wafer slice is formed of silicon oxide; and
the second bottom bonding layer is at a bottom of the second wafer slice and directly bonded with the third top bonding layer of the third wafer slice.

22. The apparatus of claim 21 wherein:
the first enhancement region includes the first barrier layer underneath the first device region and the first thermally conductive layer underneath the first barrier layer and over the first bottom bonding layer;
the first barrier layer has a thickness between 0.2 μm and 10 μm;
the first thermally conductive layer has a thickness between 0.1 μm and 20 μm;
the second passivation layer is formed of silicon oxide;
the second enhancement region includes the second barrier layer underneath the second passivation layer and the second thermally conductive layer underneath the second barrier layer and over the second bottom bonding layer;
the second barrier layer is formed of silicon nitride with a thickness between 0.2 μm and 10 μm; and
the second thermally conductive layer is formed of aluminum nitride with a thickness between 0.1 μm and 20 μm.

23. The apparatus of claim 18 wherein the third wafer slice further includes a third passivation layer underneath the third FEOL portion of the third device region, wherein the third passivation layer is formed of silicon oxide.

24. The apparatus of claim 23 wherein the third wafer slice further includes a third enhancement region underneath the third passivation layer, wherein the third enhancement region includes at least one of a third barrier layer and a third thermally conductive layer.

25. The apparatus of claim 24 wherein:
the third enhancement region includes the third barrier layer underneath the third passivation layer and the third thermally conductive layer underneath the third barrier layer;
the third barrier layer is formed of silicon nitride with a thickness between 0.2 μm and 10 μm; and
the third thermally conductive layer is formed of aluminum nitride with a thickness between 0.1 μm and 20 μm.

26. The apparatus of claim 24 further comprises a mold compound formed underneath the third enhancement region, wherein the mold compound has a thermal conductivity greater than 1 W/m·K and a dielectric constant less than 8.

27-45. (canceled)
